(19) United States
(12) Patent Application Publication
(10) Pub. No.: US 2009/0275183 A1
(43) Pub. Date: Nov. 5, 2009

(54) METHOD OF MANUFACTURING SEMICONDUCTOR DEVICE

(75) Inventors: Toshiyuki Mine, Fussa (JP); Hirotaka Hamamura, Kodaira (JP)

Correspondence Address: MATTINGLY & MALUR, P.C., 1800 DIAGONAL ROAD, SUITE 370, ALEXANDRIA, VA, 22314, US

(73) Assignee: RENESAS TECHNOLOGY CORP., Tokyo (JP)

(21) Appl. No.: 12/429,236

(22) Filed: Apr. 24, 2009

(30) Foreign Application Priority Data
May 1, 2008 (JP) 2008-119540

(51) Int. Cl. H01L 21/336; H01L 21/22; H01L 21/762

(52) U.S. Cl. 438/287; 438/542; 438/424; 257/E21.135; 257/E21.545; 257/E21.423

(57) ABSTRACT

A thermal oxidation method capable of obtaining a high oxidation rate by generating a sufficient enhanced-rate oxidation phenomenon even in a low temperature region is provided. In addition, a thermal oxidation method capable of forming a silicon oxide film having a high reliability even when formed at a low temperature region. A basic concept herein is to form a silicon oxide film by thermal reaction by generating a large amount of oxygen radicals (O*) having a large reactivity without using plasma. More specifically, ozone (O₃) and other active gas are reacted, so that ozone (O₃) is decomposed highly efficiently even in a low temperature region, thereby generating a large amount of oxygen radicals (O*). For example, a compound gas containing a halogen element can be used as the active gas.

### CROSS-REFERENCE TO RELATED APPLICATION

The present application claims priority from Japanese Patent Application No. JP 2008-119540 filed on May 1, 2008, the content of which is hereby incorporated by reference into this application.

### TECHNICAL FIELD OF THE INVENTION

The present invention relates to a technique for manufacturing a semiconductor device. More particularly, the present invention relates to a technique effectively applied to a technique for forming a silicon oxide film having a sufficiently large thickness at a relatively low temperature in the case of forming a silicon oxide film having a high reliability by a thermal oxidation method.

### BACKGROUND OF THE INVENTION

Along with miniaturization of silicon (Si) semiconductor devices, variations in threshold voltages among respective devices (respective MISFETs (Metal Insulator Semiconductor Field Effect Transistors)) have been increased and it has been a big problem in the stable operation of the devices. This is because, for example, the number of impurities to be contained in a threshold voltage adjustment semiconductor region for adjusting a threshold voltage of each device has become quite small along with miniaturization of devices, and the variations in the number and distribution of impurities have come to greatly influence the threshold voltage of each device. In other words, as the absolute number of impurities is reduced, a small variation in the number of impurities gives a great influence as a result. Therefore, along with miniaturization of devices, it has been strongly desired to develop process techniques for suppressing a variation in the number of impurities in a device. While a variation in the threshold voltage is greatly influenced by a variation in the number of impurities (impurity concentration) to be introduced to a threshold voltage adjustment semiconductor region formed in a channel region just under a gate electrode of a MISFET, other than that, it is conceivable that a variation in the threshold voltage is influenced also by a variation in the number of impurities introduced in a well in which the channel region is formed.

One of the techniques for suppressing a variation in the number of impurities is to take a technique to reduce a diffusion length of impurities. More specifically, a technique of reducing a heat treatment time and lowering a heat treatment temperature is conceivable. Particularly, lowering of the temperatures in an impurity activation processing with a high processing temperature and in a thermal oxidation processing with a high processing temperature is an important objective to be achieved in suppressing the diffusion of impurities.

First, for the suppression of impurity diffusion, it is conceivable to perform the activation of impurities at a lower temperature. However, when the heat treatment temperature is lowered in the activation of impurities, there occurs a physical problem of the decrease of an activation ratio. Accordingly, regarding the activation of impurities, it has been studied to suppress diffusion of impurities without lowering the activation ratio of impurities by reducing the time of heat treatment instead of lowering the temperature of heat treatment itself. For example, flash-lamp annealing capable of performing a heat treatment on the millisecond time scale and carbon dioxide laser annealing capable of performing a heat treatment on the microsecond time scale have been suggested. It is considered that these techniques can reduce the diffusion of impurities in a heat treatment for activating impurities.

On the contrary, since a certain period of time is required for oxidation reaction in a thermal oxidation process, only reducing time of heat treatment cannot deal with this problem. Thus, it is necessary to advance lowering of temperature of heat treatment to suppress diffusion of impurities caused by the thermal oxidation process. As one example to realize the temperature reduction of heat treatment, there is introduced a specific technique titled “ENABLING SINGLE-WAFER LOW TEMPERATURE RADICAL OXIDATION” by Yoshitaka Yokota et al. in 13th IEEE International Conference on Advanced Thermal Processing of Semiconductors—RTP 2005, pp. 139-143 (Non-Patent Document 1).

This technique described in Non-Patent Document 1 is a thermal oxidation method using a high-concentration ozone (O₃) and hydrogen as its source gases. In addition, its heating method is a lamp heating that is capable of controlling temperature in a short time. The high-concentration ozone oxidation method (O₃) using high-concentration ozone increases the thickness of a formed silicon oxide film 1.5 times thicker than a dry oxidation method (O₂) using normal oxygen when they are compared at the same heat treatment temperature and in the same oxidation time (heat treatment time). Further, as described in Non-Patent Document 1, a silicon oxide film having a thickness twice larger than that formed by the dry oxidation method can be formed in the case of performing an oxidation processing using high-concentration ozone (O₃) and hydrogen (H₂) as its source gases. Therefore, in the thermal oxidation method using high-concentration ozone (O₃) and hydrogen (H₂) as its source gases, it is considered to be possible to realize lowering of heat treatment temperature and reduction of heat treatment time more than the dry oxidation method in the case of forming a silicon oxide film having the same thickness as that formed by the dry oxidation method.

### SUMMARY OF THE INVENTION

A diffusion length of impurities such as phosphorus (P) and boron (B) introduced into a silicon substrate is determined by a square root of a product of a diffusion coefficient of the impurity (heat treatment temperature) and a heat treatment time. That is, from the view point of suppressing the diffusion of impurities, it is desirable to realize a lowering of heat treatment temperature and a reduction of heat treatment time in a heat treatment process performed on the silicon substrate after introducing the impurities. If a lowering of heat treatment temperature and a reduction of heat treatment time can be realized, it is possible to make the diffusion of impurities small, and as a result, a variation of impurity concentration (the number of impurities) can be made small.

In addition, a phenomenon that boron (B) introduced into a silicon substrate is taken into a silicon oxide film by the heat treatment, that is, a so-called boron segregation is also one cause of increasing a variation of impurity concentration, and its influence has been getting bigger along with miniaturization of devices. The boron segregation will be described specifically. For example, as illustrated in FIG. 33, a MISFET (device) is formed in an active region sandwiched between device isolation regions (STI). In other words, device isolation regions STI are separately formed in a semiconductor substrate S. This device isolation region STI has, for example, a structure in which a silicon oxide film is buried in a trench formed in the semiconductor substrate S (Shallow Trench Isolation). Further, a p-type well is formed in the active region sandwiched between the device isolation regions STI, and a channel region CH is formed in the vicinity of a surface of the semiconductor substrate S in the active region. A semiconductor region for threshold voltage adjustment VR is formed across the channel region CH until sidewalls of the device isolation regions STI. As an n-channel MISFET is intended in FIG. 33, boron is introduced into the semiconductor region for threshold voltage adjustment VR. And, a gate insulating film GOX is formed on the surface of the semiconductor substrate S, and a gate electrode G is formed on the gate insulating film GOX. Here, FIG. 33 shows a cross section taken along a gate width direction perpendicular to a gate length direction of the gate electrode G (direction sandwiched between a source region and a drain region), and a gate width W1 of FIG. 33 is illustrated. Since FIG. 33 is a cross section in the gate width direction as described in this manner, the source region and the drain region are not illustrated.

In the configuration as described above, boron introduced in the semiconductor region for threshold voltage adjustment VR formed on the sidewalls of the device isolation regions STI is taken into the inside of the device isolation regions STI (refer to the arrows in FIG. 33) when a heat treatment with large thermal load (high heat treatment temperature and long heat treatment time) is applied. As a result, a concentration of boron contained in the semiconductor region for threshold voltage adjustment VR formed on the sidewalls of the device isolation regions STI is lowered. The influence thereof occurs also at end portions of the channel region CH that is in contact with the device isolation regions STI, so that the concentration of boron is lowered at the end portions of the channel region CH. Thus, a problem of threshold voltage lowering at the end portions of the channel region CH occurs. At this time, when the gate width W1 of the MISFET is large as illustrated in FIG. 33, the influence of the lowering of boron concentration at the end portions of the channel region CH is small. However, when a gate width W2 of a MISFET is made smaller along with miniaturization of MISFETs as illustrated in FIG. 34, a percentage of the end portions of the channel region CH in the whole of channel region CH becomes larger. Therefore, in the case of the miniaturized MISFETs as illustrated in FIG. 34, boron being introduced in the end portions of the channel region CH is taken into the inside of the device isolation region STI by the heat treatment, and the influence of the so-called boron segregation increases. More specifically, as the boron segregation occurs, the lowering of threshold voltage at the end portions of the channel region CH greatly influences the characteristics of the MISFET as a result. From this fact, it is understood that it is necessary to suppress the boron segregation in the case of miniaturizing MISFETs. For the achievement of the suppression of the boron segregation, lowering of heat treatment temperature and reduction of heat treatment time are required.

While the diffusion of impurities introduced into the semiconductor substrate and the boron segregation can be made small when the oxidation temperature (heat treatment temperature) is lowered, generally, the oxidation rate is also significantly lowered. The lowering of the oxidation rate means the lengthening of the heat treatment time. Therefore, since the oxidation time (heat treatment time) is lengthened along with the lowering of oxidation temperature (heat treatment temperature) when a film thickness scaling of the silicon oxide film obtained by the oxidation is not performed, significant changes are not observed in the diffusion length of impurities and the boron segregation even when the oxidation temperature (heat treatment temperature) is lowered. That is, in the case of suppressing the variation in the concentration of impurities by lowering the oxidation temperature (heat treatment temperature), how to suppress an increase of the oxidation time (heat treatment time) is important. In other words, how much the oxidation rate can be made high is important.

Further, in a manufacture of customized products with a small production and various kinds, such as System On Chip (SOC), the wafer-by-wafer system with a short processing time is the mainstream, and it is thus important in terms of production cost that how many processes using the batch system taking a long processing time can be reduced. Meanwhile, the oxidation process in the batch system cannot be reduced in reality because, for example, there exists no apparatus of wafer-by-wafer system capable of forming a thermal oxidation film (silicon oxide film) having a thickness of about 20 nm with a high throughput.

In the thermal oxidation method using high-concentration ozone and hydrogen described as Non-Patent Document 1, while an enhanced-rate oxidation phenomenon is generated, its speed is twice the speed of the dry oxidation at most, and its effect to suppress a variation in the concentration of the impurities introduced in the semiconductor substrate is very small. In addition, since the oxidation rate is insufficient to form a thick thermal oxidation film (silicon oxide film) of about 20 nm, the thermal oxidation method using high-concentration ozone and hydrogen is difficult to be applied in terms of throughput.

An object of the present invention is to provide a thermal oxidation method in which a sufficient enhanced-rate oxidation phenomenon is generated even in a low-temperature region and a high oxidation rate can be obtained. In addition, another object of the present invention is to provide a thermal oxidation method capable of forming a silicon oxide film having a high reliability even when it is formed in a low-temperature region.

The above and other objects and novel characteristics of the present invention will be apparent from the description of the present specification and the accompanying drawings.

The typical ones of the inventions disclosed in the present application will be briefly described as follows.

A method of manufacturing a semiconductor device according to a typical embodiment is a method of manufacturing a semiconductor device for manufacturing a semiconductor device including a MISFET, and the method includes the steps of: (a) introducing impurities into a semiconductor substrate, thereby forming a semiconductor region; and (b) performing a thermal oxidation on the semiconductor substrate or a processed film on the semiconductor substrate, thereby forming a silicon oxide film after the step (a). At this time, the step (b) includes the steps of: (b1) introducing source gases including a gas containing ozone and a compound gas containing a halogen element onto the semiconductor substrate; and (b2) heating the semiconductor substrate after the step (b1).

The effects obtained by typical aspects of the present invention will be briefly described below.

It is possible to provide a thermal oxidation method in which a sufficient enhanced-rate oxidation phenomenon is generated even in a low-temperature region and a high oxidation rate can be obtained. In addition, it is possible to provide a thermal oxidation method capable of forming a silicon oxide film having a high reliability even when it is formed in a low-temperature region.

### BRIEF DESCRIPTIONS OF THE DRAWINGS

FIG. 1 is a plan view illustrating a plane configuration of an oxidation apparatus used in a first embodiment of the present invention;

FIG. 2 is a cross-sectional view of a part of FIG. 1 taken along the line A-A;

FIG. 3 is a flowchart illustrating a flow of a thermal oxidation method according to the first embodiment;

FIG. 4 is a graph illustrating a HCl concentration dependency of a film-formation rate of a formed silicon oxide film;

FIG. 5 is a table for specifying a combination of source gases by which an enhanced-rate oxidation phenomenon is generated;

FIG. 6 is a graph illustrating a relationship of a thickness and an oxidation temperature of the formed silicon oxide film;

FIG. 7 is a graph illustrating a relationship of a density of chlorine elements contained in the formed silicon oxide film and a concentration of hydrogen chloride added in the source gas;

FIG. 8A is a diagram illustrating a method of supplying source gases according to a second embodiment;

FIG. 8B is a diagram illustrating a method of supplying source gases according to the second embodiment;

FIG. 9 is a graph illustrating that there is a difference in a thickness uniformity of a silicon oxide film formed on a semiconductor substrate depending on a difference in methods of supplying source gases;

FIG. 10 is a diagram illustrating a configuration of an oxidation apparatus of a shower-head type;

FIG. 11 is a diagram illustrating a configuration of a shower head;

FIG. 12 is a table illustrating thicknesses of silicon oxide films formed on various bases for comparison according to a third embodiment;

FIG. 13 is a cross-sectional view illustrating a step of planarizing an irregular form formed on a surface of a semiconductor substrate;

FIG. 14 is a cross-sectional view illustrating a step continued from FIG. 13;

FIG. 15 is a cross-sectional view illustrating a step continued from FIG. 14;

FIG. 16 is a cross-sectional view illustrating a manufacturing step of a semiconductor device according to a fourth embodiment;

FIG. 17 is a cross-sectional view illustrating a manufacturing step of a semiconductor device continued from FIG. 16;

FIG. 18 is a cross-sectional view illustrating a manufacturing step of a semiconductor device continued from FIG. 17;

FIG. 19 is a cross-sectional view illustrating a manufacturing step of a semiconductor device continued from FIG. 18;

FIG. 20 is a cross-sectional view illustrating a manufacturing step of a semiconductor device continued from FIG. 19;

FIG. 21 is a cross-sectional view illustrating a manufacturing step of a semiconductor device continued from FIG. 20;

FIG. 22 is a cross-sectional view illustrating a manufacturing step of a semiconductor device continued from FIG. 21;

FIG. 23 is a cross-sectional view illustrating a manufacturing step of a semiconductor device continued from FIG. 22;

FIG. 24 is a cross-sectional view illustrating a manufacturing step of a semiconductor device continued from FIG. 23;

FIG. 25 is a cross-sectional view illustrating a manufacturing step of a semiconductor device continued from FIG. 24;

FIG. 26 is a cross-sectional view illustrating a manufacturing step of a semiconductor device continued from FIG. 25;

FIG. 27 is a cross-sectional view illustrating a manufacturing step of a semiconductor device according to a fifth embodiment;

FIG. 28 is a cross-sectional view illustrating a manufacturing step of a semiconductor device continued from FIG. 27;

FIG. 29 is a cross-sectional view illustrating a manufacturing step of a semiconductor device continued from FIG. 28;

FIG. 30 is a cross-sectional view illustrating a manufacturing step of a semiconductor device continued from FIG. 29;

FIG. 31 is a cross-sectional view illustrating a manufacturing step of a semiconductor device continued from FIG. 30;

FIG. 32 is a cross-sectional view illustrating a manufacturing step of a semiconductor device continued from FIG. 31;

FIG. 33 is a cross-sectional view studied by the inventors of the present invention and illustrating a channel region formed between device isolation regions mainly in the case a large gate width; and

FIG. 34 is a cross-sectional view studied by the inventors of the present invention and illustrating a channel region formed between device isolation regions mainly in the case of a small gate width.

### DESCRIPTIONS OF THE PREFERRED EMBODIMENTS

In the embodiments described below, the invention will be described in a plurality of sections or embodiments when required as a matter of convenience. However, these sections or embodiments are not irrelevant to each other unless otherwise stated, and the one relates to the entire or a part of the other as a modification example, details, or a supplementary explanation thereof.

Also, in the embodiments described below, when referring to the number of elements (including number of pieces, values, amount, range, and the like), the number of the elements is not limited to a specific number unless otherwise stated or except the case where the number is apparently limited to a specific number in principle. The number larger or smaller than the specified number is also applicable.

Further, in the embodiments described below, it goes without saying that the components (including element steps) are not always indispensable unless otherwise stated or except the case where the components are apparently indispensable in principle.

Similarly, in the embodiments described below, when the shape of the components, positional relation thereof, and the like are mentioned, the substantially approximate and similar shapes and the like are included therein unless otherwise stated or except the case where it can be conceived that they are apparently excluded in principle. The same goes for the numerical value and the range described above.

Also, components having the same function are denoted by the same reference symbols throughout the drawings for describing the embodiments, and the repetitive description thereof is omitted. Also, in some drawings used in the embodiments, hatching is used even in a plan view so as to make the drawings easy to see.

### First Embodiment

Prior to describing embodiments of the present invention, a basic concept of the present invention will be described. The basic concept of the present invention lies in that a silicon oxide film is formed by thermal reaction made by generating a large amount of oxygen radicals having a large reactivity without using plasma. More specifically, in the case of using plasma, there are not only radical species but also ion species present in the plasma. Therefore, the formed silicon oxide film becomes prone to be damaged due to a sputtering phenomenon by the ion species during forming the silicon oxide film. From this reason, the formed silicon oxide film is frequently damaged in the method of using plasma, and it is thus difficult to form a highly reliable silicon oxide film. On the contrary, according to the present invention, a highly reliable silicon oxide film is formed by performing a thermal oxidation using oxygen radicals having a large reactivity and containing no ion species. In addition, the present invention includes a mechanism for generating a large amount of oxygen radicals, and thus, a highly reliable silicon oxide film can be sufficiently formed even when using a thermal oxidation method in a low temperature.

More specifically, the present invention has a feature of reacting ozone (O₃) and other active gas to decompose ozone (O₃) highly efficiently even in a low temperature region, thereby generating a large amount of oxygen radicals (O*). For example, as the active gas, a compound gas containing a halogen element and so forth can be used. As the compound gas containing a halogen element, there are hydrogen compounds such as hydrogen fluoride (HF), hydrogen chloride (HCl), hydrogen bromide (HBr), etc. In addition, compound gases containing a halogen element such as nitrogen trifluoride (NF₃), chlorine trifluoride (ClF₃), etc. can be used.

While any of a heater heating method, a lamp heating method and an induction heating method can be applied to a heating method of a substrate to be oxidized (semiconductor substrate), it is necessary to ensure a film-thickness uniformity of the silicon oxide film in any cases. More specifically, to ensure a film-thickness uniformity of the silicon oxide film, it is important to make a concentration of the source gas uniform just above the substrate to be oxidized (semiconductor substrate). Thus, there is a suitable method of introducing the source gas for each heating method of heating the substrate to be oxidized (semiconductor substrate). In addition, since a compound gas containing a halogen element is used for a part of the source gas, it is preferred to provide a load-lock chamber to a heating apparatus so as to prevent the moisture in the air from entering in a reaction furnace.

In the thermal oxidation method used in the present invention, a silicon substrate (Si substrate) and a silicon carbide substrate (SiC substrate) are intended as the substrate to be oxidized. In addition, the thermal oxidation method used in the present invention can be applied to the case of forming a silicon oxide film by oxidizing a thin film formed on the semiconductor substrate. In this case, for example, a polycrystalline silicon film (polysilicon film), a silicon carbide film, a silicon nitride film, etc. are intended as the thin film formed on the semiconductor substrate. Note that these materials to be oxidized are examples and the thermal oxidation method according to the present invention can be adopted as long as the material is capable of generating an oxidation reaction.

An important point in the present invention is that an oxidizing gas having a predetermined flow rate is introduced in advance into a reaction chamber when heating the substrate to be oxidized (semiconductor substrate). When the substrate to be oxidized (semiconductor substrate) is heated with introducing the halogen-containing compound gas alone, a gas-phase etching is generated in the case of a silicon substrate or a silicon carbide substrate. More specifically, since the halogen-containing compound gas has a function of etching a surface of the silicon substrate and a surface of the silicon carbide substrate, when the halogen-containing compound gas is introduced into the reaction chamber in which the silicon substrate or the silicon carbide substrate is placed, the timing thereof is important. For example, even when an oxidizing gas and a halogen-containing compound gas are introduced simultaneously, a gas-phase etching is generated when a partial pressure of the oxidizing gas is small. Therefore, also in the case of simultaneously introducing an oxidizing gas and a halogen-containing compound gas, it is important to adjust the flow rate ratio thereof so as not to generate a gas-phase etching.

A feature of the present invention lies in that an oxidizing gas containing ozone (O₃) and a compound gas containing a halogen element are used as source gases so that dissociation of ozone (O₃) is accelerated even in a low temperature region, thereby generating a large amount of oxygen radicals having a rich reactivity. By generating a large amount of oxygen radicals in this manner, formation of a silicon oxide film is accelerated. In other words, in the present invention, an oxidizing gas containing ozone (O₃) and a compound gas containing a halogen element are used as source gases, whereby an enhanced-rate oxidation phenomenon that accelerates the formation of a silicon oxide film is generated.

In the following, a principle of generating the enhanced-rate oxidation phenomenon will be briefly described. Here, an example where a thermal oxidation film (silicon oxide film) is formed on a surface of a silicon substrate with using the most general lamp heating apparatus of a tungsten halogen lamp system will be described. As already known, the lamp heating method is a method for directly heating a silicon substrate by radiating light having a wavelength absorbable by the silicon substrate. Generally, a method of heating only the silicon substrate without heating the inside of the reaction chamber is employed in the lamp heating method. For the formation of a silicon oxide film using the thermal oxidation method, ozone (O₃) and a hydrogen compound gas such as hydrogen chloride (HCl) are introduced into a reaction chamber with a predetermined flow rate ratio. At this time, when the silicon substrate is heated by the lamp heating method, only the silicon substrate becomes a high temperature. In the case of a thermal oxidation method using only ozone (O₃) as its source gas, ozone (O₃) in the vicinity of the silicon substrate is thermally dissociated to be oxygen (O₂) and oxygen radical (O*). This oxygen radical (O*) generated by thermal dissociation has a very strong oxidizability, and the silicon substrate is oxidized even in a low temperature. However, in the case of using only ozone (O₃) as the source gas, the generation efficiency of oxygen radical (O*) is small because oxygen radical (O*) is formed only by thermal dissociation reaction, so that an oxidation rate that is only about 1.5 times the oxidation rate of the dry oxidation using normal oxygen (O₂) is obtained.

In contrast, hydrogen chloride (HCl) is also thermally dissociated in the vicinity of the silicon substrate in the present invention, so that hydrogen radical (H*) and chlorine radical (Cl*) are generated. Both of the radicals (hydrogen radical (H*) and chlorine radical (Cl*)) are very active and they easily decompose ozone (O₃) when they contact with ozone (O₃), so that a large amount of oxygen radicals (O*) are generated. Particularly, radicals of halogen elements have a large reactivity, and a generation efficiency of oxygen radical (O*) is significantly increased when introducing ozone (O₃) and hydrogen chloride (HCl) simultaneously, and as a result, the oxidation reaction on the silicon substrate becomes much faster.

As described above, in the present invention, by not only generating oxygen radicals by thermal dissociation of ozone (O₃) itself, but also generating a large amount of oxygen radicals (O*) by using the decomposition of ozone (O₃) by the hydrogen radicals (H*) and chlorine radicals (Cl*) generated by thermal dissociation of hydrogen chloride (HCl), the oxidation reaction on the silicon substrate is accelerated. That is, the basic concept of the present invention is to generate an enhanced-rate oxidation phenomenon in the formation of a silicon oxide film by simultaneously using a gas having a catalyst function for accelerating the decomposition of ozone (O₃). Herein, it is important to make a thermal decomposition of a gas to be a catalyst and a reaction with ozone (O₃) happen in the vicinity of a surface of a material to be oxidized. For this purpose, it is important to select the most suitable method for introducing a source gas for each method of heating a semiconductor substrate.

Further, since the present invention does not use plasma for generating radicals, it is has an advantage that no plasma damage is caused on the silicon oxide film to be formed. Moreover, since an energy distribution of radicals generated by the reaction with the catalyst gas is more regular than that of radicals generated by plasma excitation, the thermal oxidation method of the present invention also has a feature of obtaining a more uniform film quality than the plasma oxidation method.

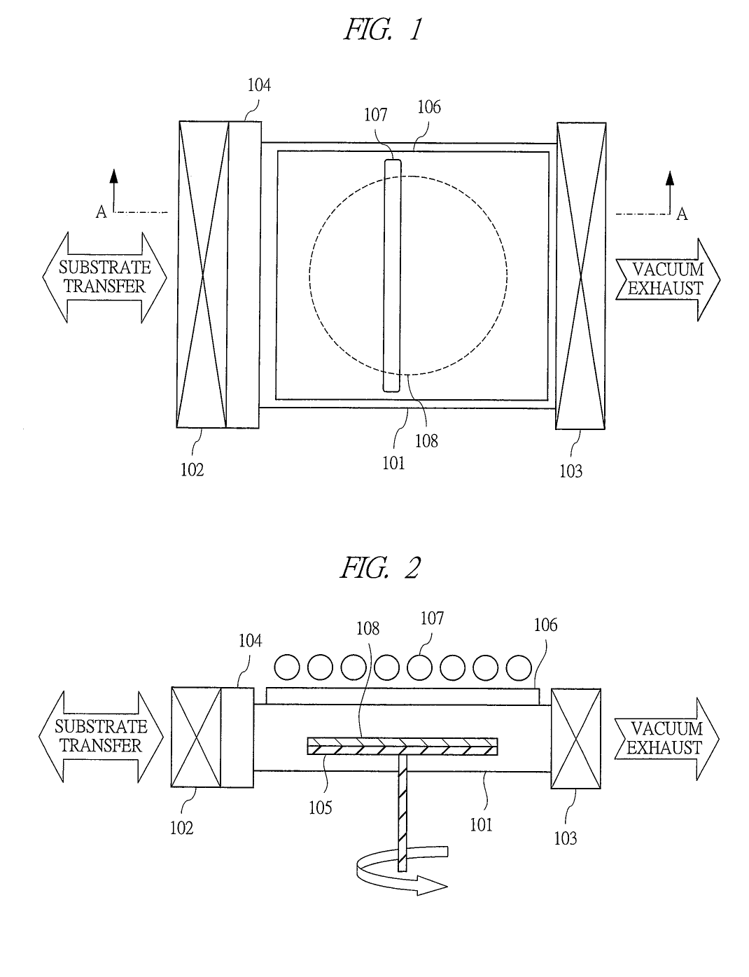

Next, detailed descriptions will be made about the thermal oxidation method according to the embodiments of the present invention with reference to accompanied drawings. FIG. 1 is a plan view of a heat treatment apparatus according to a first embodiment of the present invention. And, FIG. 2 is a cross-sectional view of a part of the heat treatment apparatus cut along the line A-A of FIG. 1. Though omitted in FIG. 1 and FIG. 2, a substrate transfer chamber having a vacuum exhaust mechanism is installed on the left side of the figures, and a semiconductor substrate 108 can be introduced into and discharged from a reaction chamber 101 via a gate bulb 102. It is structured such that the semiconductor substrate 108 introduced into the reaction chamber 101 is set on a holding table 105 capable of rotating the semiconductor substrate 108. It is structured such that pressure in the reaction chamber 101 is controllable from the air pressure to vacuum (to 10 mPa), a oxidizing gas (including ozone (O₃)) and hydrogen chloride (HCl) are introduced from a gas introduction block 104 arranged on the left side of FIG. 1 and FIG. 2, and these oxidizing gas and hydrogen chloride are exhausted through an exhaust bulb 103 illustrated on the right side of FIG. 1 and FIG. 2. For the heating of the semiconductor substrate 108, a tungsten halogen lamp 107 (only one piece is described in the plan view (FIG. 1)) is used, and it is structured such that light is irradiated on the semiconductor substrate 108 through a quartz window 106 provided on an upper portion of the reaction chamber 101, thereby heating the semiconductor substrate 108.

The heat treatment apparatus according to the first embodiment is structured as the following. Hereinafter, a thermal oxidation method according to the first embodiment using the above-described heat treatment apparatus will be described.

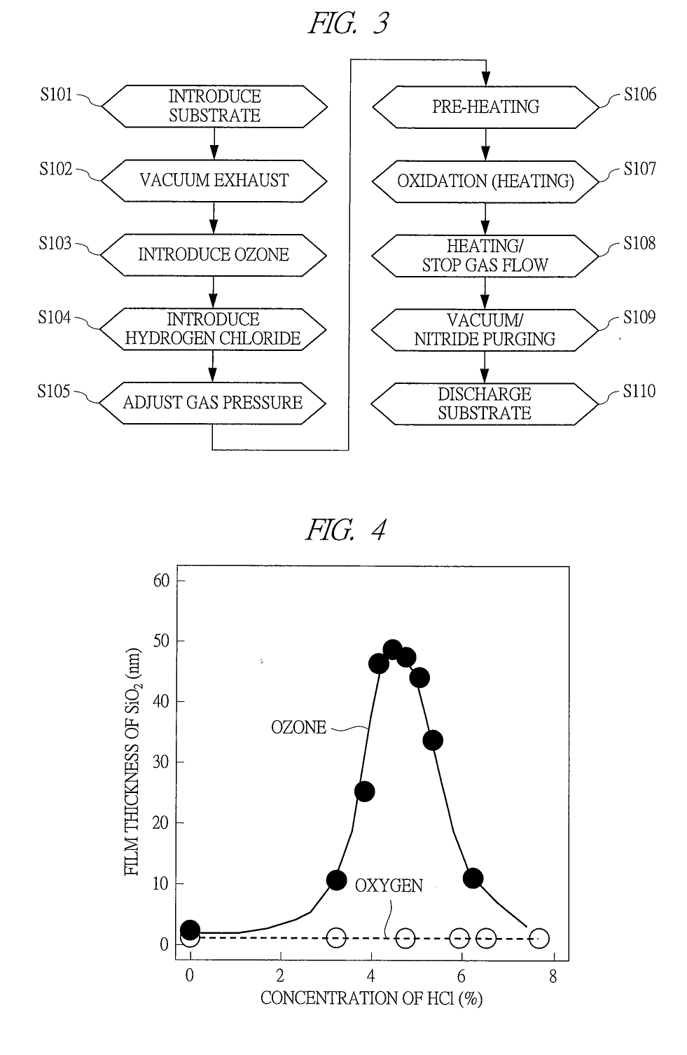

FIG. 3 is a diagram showing one example of a process flow of the heat treatment method according to the first embodiment. An important point in the first embodiment is that an oxidizing gas having a predetermined flow rate is introduced in the reaction chamber 101 beforehand when heating the substrate to be oxidized (semiconductor substrate). The oxidizing gas is, for example, a gas containing oxygen (O₂) and ozone (O₃). In the following, details of the process flow will be described with reference to FIG. 1 to FIG. 3.

First, the semiconductor substrate 108 that is a silicon substrate of, for example, 8 inch is introduced into the reaction chamber 101 from the substrate transfer chamber (S101). In the first embodiment, a small amount of nitrogen is flowed into the substrate transfer chamber and the reaction chamber 101, and the semiconductor substrate 108 is transferred in a pressure of about 20 Pa.

Next, the introduction of nitrogen is stopped, and the reaction chamber 101 is vacuum exhausted until the pressure in the reaction chamber 101 becomes lower than or equal to 10 mPa (S102). Subsequently, with introducing 90% of ozone (O₃) into the reaction chamber 101 at a predetermined flow rate (S103), the holding table 105 is rotated at a rate of 60 rotations per minute, and then hydrogen chloride (HCl) is introduced at a predetermined flow rate (S104). As it will be described later, the enhanced-rate oxidation phenomenon according to the first embodiment is strongly dependent on a flow rate ratio (HCl concentration) of ozone (O₃) and hydrogen chloride (HCl). Therefore, by adjusting an oxidation temperature (heat treatment temperature), an HCl concentration and an oxidation time (heat treatment time), a silicon oxide film having a desired thickness can be obtained. In the first embodiment, the oxidizing gas containing ozone (O₃) is first introduced into the reaction chamber 101, and then hydrogen chloride (HCl) is introduced into the reaction chamber 101. This is because a gas-phase etching occurs on a surface of the semiconductor substrate 108 when hydrogen chloride (HCl) is introduced first as described above. In order to suppress this gas-phase etching, the oxidizing gas containing ozone (O₃) is first introduced into the reaction chamber 101 in the first embodiment.

Next, the gas pressure inside the reaction chamber 101 is adjusted by adjusting the exhaust bulb 103 (S105). The gas pressure of the reaction chamber 101 greatly influences the film-thickness uniformity of the silicon oxide film to be formed. More specifically, since a HCl concentration distribution on the surface of the semiconductor substrate 108 is changed in accordance with a flow rate of the source gases, the gas pressure inside the reaction chamber 101 is preferably set so that the film-thickness uniformity of the silicon oxide film to be formed is optimized. In the first embodiment, for example, the pressure in the reaction chamber 101 after introducing gases is set to about 1330 Pa.

Subsequently, after confirming that the gas pressure inside the reaction chamber 101 is stable, a pre-heating of the semiconductor substrate 108 is performed by energizing the tungsten halogen lamp 107 (S106). The pre-heating step is not indispensable but is very effective to uniform the temperature of the semiconductor substrate 108. In the first embodiment, for example, the pre-heating at a temperature of 300° C. and for about 30 seconds is performed. Note that, in the pre-heating, a silicon oxide film is slightly formed (1 nm or thinner) on the semiconductor substrate 108 by ozone (O₃).

Next, a temperature of the semiconductor substrate 108 is raised to a predetermined temperature to oxidize the semiconductor substrate 108 (S107). In the first embodiment, the oxidation temperature of the semiconductor substrate 108 is set to 800° C., and the oxidation time is set to 2 minutes. Subsequently, after turning off the power of the tungsten halogen lamp 107 and stopping the introduction of gases (S108), a vacuum purge and a nitrogen purge are sufficiently performed (S109). Finally, after stopping the rotation of the holding table 105, the semiconductor substrate 108 is discharged from the reaction chamber 101 (S110). In the above-described manner, the thermal oxidation method according to the first embodiment is carried out, so that a silicon oxide film is formed on the surface of the semiconductor substrate 108.

Hereinafter, the first embodiment in which the silicon oxide film is formed on the semiconductor substrate by the above-described thermal oxidation method will be described in detail. First, the enhanced-rate oxidation phenomenon observed in the thermal oxidation method according to the first embodiment will be described.

FIG. 4 shows a HCl concentration dependency of the thermal oxidation film (silicon oxide film) obtained by an oxidation (heat treatment) with a heat treatment temperature (oxidation temperature) of 800° C. and a heat treatment time (oxidation time) of 2 minutes. The HCl concentration is defined as “HCl flow rate/(HCl flow rate+oxidizing gas flow rate)”. In the first embodiment, a comparison between a sample of the case of using ozone (O₃) as the oxidizing gas and a sample of the case of using oxygen (O₂) as the oxidizing gas is described. The black circle in FIG. 4 indicates a result of the case of using ozone (O₃), and the white circle in FIG. 4 indicates a result of the case of using oxygen (O₂).

As shown in FIG. 4, in the thermal oxidation method using oxygen (O₂) and hydrogen chloride (HCl), almost no change is observed in the thickness of the silicon oxide film even when the HCl concentration is changed, and this is almost the same result as the dry oxidation using normal oxygen (O₂) only. On the contrary, as shown in FIG. 4, in the thermal oxidation method using ozone (O₃) and hydrogen chloride (HCl), the thickness of the silicon oxide film is increased along with the increase of the HCl concentration, and an enhanced-rate oxidation phenomenon in which the thickness of the silicon oxide film reaches maximum at a HCl concentration of about 4.5% is observed. In addition, when the HCl concentration is further increased, the thickness of the silicon oxide film formed by the thermal oxidation is decreased. This is because etching of the silicon oxide film by chloride (Cl) becomes dominant than the formation of the silicon oxide film, and it indicates that there is an optimum value of the HCl concentration in the thermal oxidation method using ozone (O₃) and hydrogen chloride (HCl). More specifically, it can be understood that, since the catalyst gas used in the first embodiment is a compound gas containing a halogen element, the silicon oxide film is etched when the halogen-containing compound gas is supplied at an excessively high concentration, and there is a region where the oxidation rate is adversely lowered. Therefore, in the thermal oxidation method using ozone (O₃) and the halogen-containing compound gas as its source gases, it is important to use the halogen-containing compound gas at a concentration, in which the film-formation rate (oxidation rate) of the silicon oxide film becomes the maximum value, or lower. For example, to describe with reference to FIG. 4, since the thickness of the silicon oxide film becomes the maximum value at the point where the HCl concentration is 4.5%, it can be understood that the thermal oxidation method according to the first embodiment is preferably performed at the HCl concentration of 4.5% or lower.

On the other hand, although not shown in FIG. 4, it has been revealed that the ozone concentration of the supplied ozone (O₃) also greatly influences the enhanced-rate oxidation phenomenon. Though the result shown in FIG. 4 is the result of using ozone (O₃) with an ozone concentration of about 90%, it has been found that the enhanced-rate oxidation phenomenon is rapidly decreased when the ozone concentration is lowered. In the range of the studies of the first embodiment, the advantage of the enhanced-rate oxidation phenomenon has been observed when the ozone concentration is 50% or higher, and almost no effect (advantage) of adding the catalyst gas has been observed when the ozone concentration is 50% or lower. Therefore, in the thermal oxidation method using ozone and a compound gas containing a halogen element, it is preferred to use ozone with an ozone concentration of 50% or higher. Note that, although FIG. 4 shows the oxidation processing with the oxidation temperature (heat treatment temperature) of 800° C. and the oxidation time (heat treatment time) of 2 minutes, it has been found that the thickness of the silicon oxide film of about 100 nm or smaller can be arbitrary controlled by appropriately selecting the oxidation temperature (heat treatment temperature), the oxidation time (heat treatment time) and the HCl concentration. Herein, when ozone concentration is mentioned in the present specification, it means an ozone concentration in the gas (oxidizing gas) containing ozone defined by “ozone flow rate/(ozone flow rate+oxygen flow rate)×100”.

Subsequently, in order to examine the influence of the halogen elements in the enhanced-rate oxidation phenomenon, the occurrence of the enhanced-rate oxidation phenomenon has been examined in detail with changing the combinations of the oxidizing gas and the halogen-containing gas, and the results of the examination will be described. Examples where three kinds of gases of (1) ozone (O₃), (2) oxygen (O₂) and (3) water (H₂+O₂) are selected as the oxidizing gases and (a) hydrogen chloride (HCl) and (b) chlorine (Cl₂) are selected as the chlorine-containing gas will be shown. Conditions of the oxidation are an oxidation temperature of 800° C. and an oxidation time of 2 minutes. The occurrence of the enhanced-rate oxidation phenomenon is defined by whether the difference in thickness between the silicon oxide film in the case of not adding the chlorine-containing gas and the silicon oxide film in the case of adding the chlorine-containing gas is twice or more. FIG. 5 is a table listing the result. In FIG. 5, the circle indicates that the enhanced-rate oxidation phenomenon exists, and the cross indicates that the enhanced-rate oxidation phenomenon does not exist. As is apparent from FIG. 5, the enhanced-rate oxidation phenomenon is observed only in the case of using ozone (O₃) and hydrogen chloride (HCl). More specifically, it can be understood that the occurrence of the enhanced-rate oxidation phenomenon by the thermal oxidation method can be achieved by using, for example, an oxidizing gas containing ozone (O₃) and hydrogen chloride (HCl) as source gases.

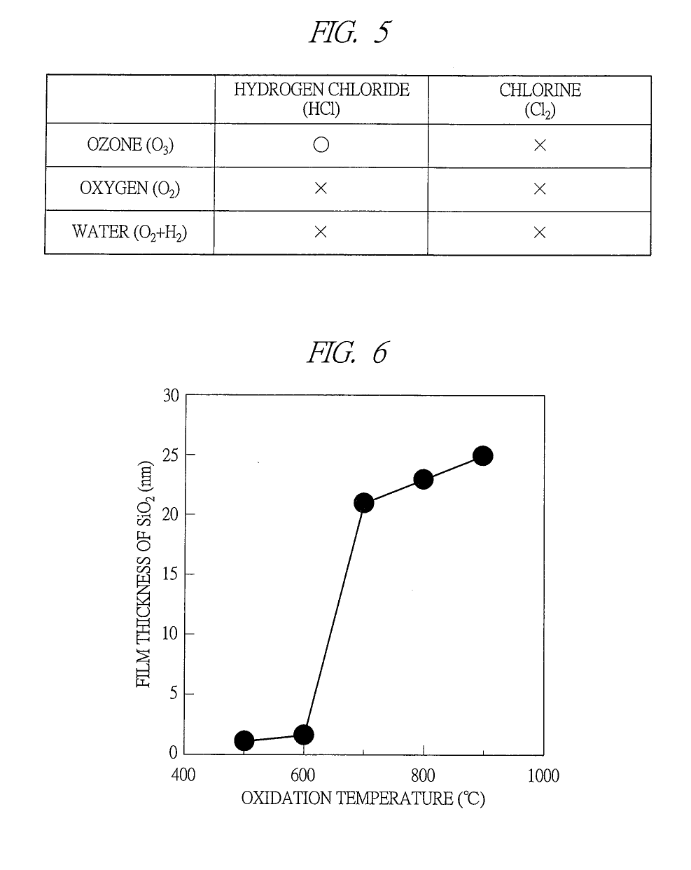

Subsequently, a dependency of the oxidation temperature in the combination of ozone (O₃) and hydrogen chloride (HCl) where the enhanced-rate oxidation phenomenon is observed has been examined, and the result of the examination will be described. As the conditions of the experiment described below, a gas flow rate (HCl concentration), a gas pressure and an oxidation time are fixed, and only an oxidation temperature is changed. The result of the experiment is illustrated in FIG. 6. A SiO₂ film thickness ratio on the vertical axis is represented by a film thickness ratio of the silicon oxide film in the case of adding hydrogen chloride (HCl) to the film thickness of the silicon oxide film in the case of not adding hydrogen chloride (HCl). In FIG. 6, the region where the film thickness ratio of the silicon oxide film is rapidly increased indicates an occurrence of the enhanced-rate oxidation phenomenon. As is evident from the first embodiment, the enhanced-rate oxidation phenomenon is not generated in the range of the oxidation temperature of 500 to 600° C., and the enhanced-rate oxidation phenomenon is generated in the range of higher than or equal to 700° C. This is caused by the thermal dissociation of hydrogen chloride (HCl) generated around 700° C. and the rapid decomposition of ozone (O₃) by the chlorine radicals (Cl*) and hydrogen radicals (H*) generated by the thermal dissociation. Accordingly, the most important point in the first embodiment is to use the gas thermally dissociated and having a catalyst function to decompose ozone (O₃) (for example, hydrogen chloride (HCl)) and ozone (O₃) at the same time, and to use a gas having a catalyst function and decomposable at a low temperature. In other words, while the oxidation temperature of, for example, 800° C. or higher is required in the normal thermal oxidation method, the enhanced-rate oxidation phenomenon can be generated when the temperature is higher than or equal to a temperature at which the compound gas containing a halogen element is thermally dissociated in the first embodiment. For example, as shown in FIG. 6, since hydrogen chloride (HCl) is thermally dissociated at about 700° C. in the case of using hydrogen chloride (HCl) as the catalyst gas, the silicon oxide film can be sufficiently formed by generating the enhanced-rate oxidation phenomenon at 700° C. or higher in the thermal oxidation method according to the first embodiment. In other words, the lower the thermal dissociation temperature of the catalyst gas is, the more efficiently the thermal oxidation method of the first embodiment can generate the enhanced-rate oxidation phenomenon even at a low temperature, so that the silicon oxide film can be sufficiently formed.

For example, the same effects can be obtained also by using a compound gas of a halogen element and hydrogen such as hydrogen fluoride (HF) and hydrogen bromide (HBr) instead of hydrogen chloride (HCl). To be exact, when hydrogen bromide (HBr) that is thermally unstable than hydrogen chloride (HCl) is used, the enhanced-rate oxidation phenomenon can be generated in a lower temperature region. In addition, it has been revealed that the enhanced-rate oxidation phenomenon can be generated in a low temperature region also by using compound gases containing halogen elements such as nitrogen trifluoride (HF₃) and chlorine trifluoride (ClF₃) although there are some differences in decomposition temperature.

Note that, while the oxidation processing of the semiconductor substrate has been performed while supplying ozone (O₃) having an ozone concentration of 90% within the range of 300 to 800 cc per minute in the thermal oxidation method according to the first embodiment, it has been revealed that the oxidation rate to form the silicon oxide film is of course increased in the region where the ozone flow rate is high if the oxidation reaction is within the supply-controlled temperature range. Similarly, the higher the ozone concentration is, the higher the oxidation rate to form the silicon oxide film becomes. In addition, with respect to the flow rate of hydrogen chloride (HCl) to be the catalyst gas, it has been revealed that the oxidation rate to form the silicon oxide film becomes high in the region where the flow rate of hydrogen chloride (HCl) is high.

The thermal oxidation method of the first embodiment has been described in the foregoing, but characteristic traces are formed in the silicon oxide film when the thermal oxidation method of the first embodiment is used. One of the characteristic phenomena will be described. In the traditional oxidation processing of a semiconductor substrate which uses oxygen (O₂) and hydrogen chloride (HCl) (referred to as HCl oxidation), chlorine elements (Cl) are contained in the formed silicon oxide film. Chlorine (Cl) is similarly contained in the silicon oxide film formed by the thermal oxidation method of the first embodiment, and a concentration of chlorine contained in the silicon oxide film depends on the HCl concentration in the source gas atmosphere in the oxidation processing.

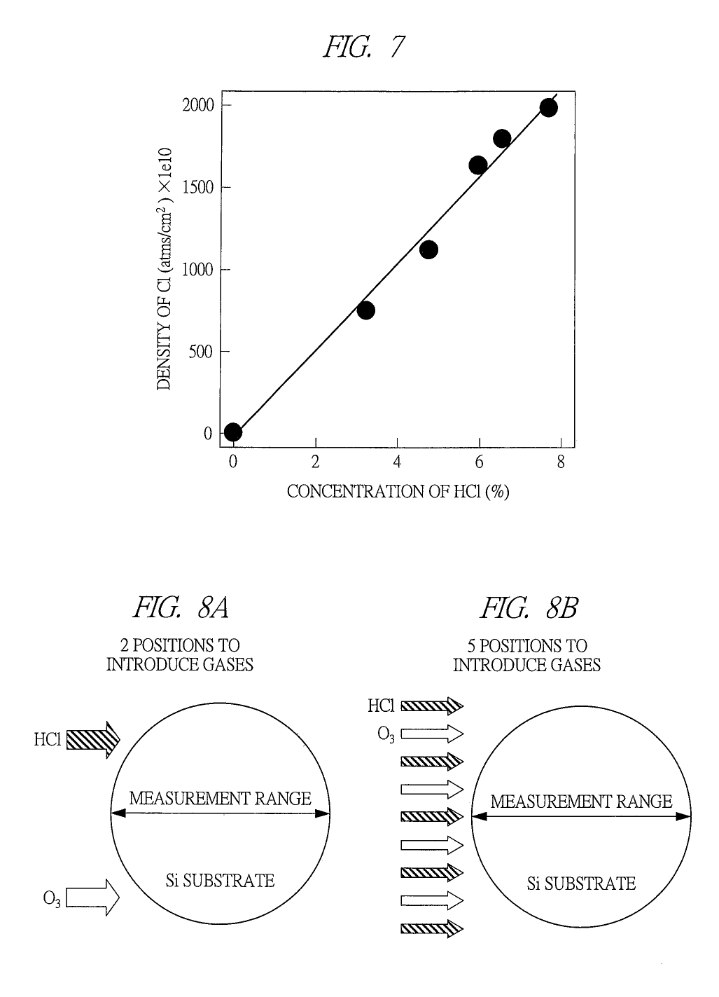

FIG. 7 is a graph illustrating chlorine concentrations in the silicon oxide films formed by oxidizations with respective HCl concentrations. In FIG. 7, the thickness of the silicon oxide film is set to be constant at 4 nm, and FIG. 7 shows the surface densities of chlorine (Cl) measured by using the total reflection fluorescence X-ray. As shown in FIG. 7, the chlorine concentration in the silicon oxide film has a liner relation to the HCl concentration in the oxidizing atmosphere. As compared with the silicon oxide film formed with the same oxidizing temperature and the same chlorine concentration (HCl) as the conventional HCl oxidation, it has been revealed that the silicon oxide film formed in the first embodiment contains more chlorine elements than the conventional HCl oxidation. This indicates that chlorine elements in the oxidizing atmosphere become active chlorine radicals in the first embodiment. In addition, although the example of the thermal oxidation method using ozone (O₃) and hydrogen chloride (HCl) has been described in the first embodiment, elements of the compound gas containing a halogen element have been contained in the silicon oxide film and an interface between the semiconductor substrate and the silicon oxide film in the case of using, for example, hydrogen fluoride (HF), hydrogen bromide (HBr), nitrogen trifluoride (HF₃) or chlorine trifluoride (ClF₃). In this manner, a feature of the thermal oxidation method in the first embodiment lies in that the elements of the halogen-containing compound gas are taken into the silicon oxide film.

### Second Embodiment

Next, a second embodiment will be described in detail. Herein, a film thickness uniformity of a thermal oxide film (silicon oxide film) to be obtained in the second embodiment will be described. In the case of using the heat treatment apparatus (oxidation apparatus) illustrated in FIG. 1 and FIG. 2 to carry out a thermal oxidation method by ozone (O₃) and hydrogen chloride (HCl), uniformity of the thermal oxide film greatly differs depending on a supplying method of the source gases (ozone (O₃) and hydrogen chloride (HCl)). More specifically, in the case of supplying ozone (O₃) and hydrogen chloride (HCl) from the gas introduction block 104 illustrated in FIG. 1 and FIG. 2, the thickness of the obtained thermal oxide film (silicon oxide film) is greatly changed depending on respective gas introduction positions and the number of introduction lines.

FIG. 8A and FIG. 8B are diagrams illustrating positional relationships of a semiconductor wafer (semiconductor substrate) and gas introduction positions and the number of introduction lines of the source gases. FIGS. 8A and 8B correspond to the plan view of FIG. 1. FIG. 8A illustrates the case of supplying ozone (O₃) and hydrogen chloride (HCl) to the semiconductor substrate (semiconductor wafer) from the left side to describe a supplying method of source gases, in which an introduction tube for supplying ozone (O₃) is provided at one position and an introduction tube for supplying hydrogen chloride (HCl) is provided at one position, respectively. In contrast, FIG. 8B illustrates the case of supplying ozone (O₃) and hydrogen chloride (HCl) to the semiconductor substrate (semiconductor wafer) from the left side to describe a supplying method of source gases, in which the introduction tubes for supplying hydrogen chloride (HCl) are provided at five positions and the introduction tubes for supplying ozone (O₃) are provided at four positions and these tubes for respective source gases are alternately arranged. In the second embodiment, the thermal oxidation method was carried out with using these two types of supplying methods of source gases shown in FIGS. 8A and 8B, and the film thickness uniformity in the plane of the semiconductor substrate (semiconductor wafer) was examined. Herein, the semiconductor substrate was rotated at a rate of 60 rotations per minute, and the thermal oxidation method was carried out in the same conditions for both of the supplying methods of source gases. Note that, in both the supplying methods of source gases, the flow rates of ozone (O₃) and hydrogen chloride (HCl) are the same.

FIG. 9 is a graph showing results of comparisons of film thickness distributions in the plane of the semiconductor substrate in the case where the thermal oxidation method is carried out with both of the supplying methods of source gases. In the case of carrying out the thermal oxidation method with the supplying method of source gases shown in FIG. 8A, a convexed form of film thickness distribution is displayed where the silicon oxide film becomes thicker as it gets closer to the center portion of the semiconductor substrate. On the contrary, in the case of carrying out the thermal oxidation method with the supplying method of source gases of FIG. 8B, there is no large difference in the thickness of the silicon oxide film between edge portions and the center portion of the semiconductor substrate, and it can be understood that a uniform film thickness distribution is obtained over the whole surface of the semiconductor substrate.

In the thermal oxidation method according to the second embodiment, since the enhanced-rate oxidation phenomenon is generated by chlorine radicals (Cl*) and hydrogen radicals (H*) obtained by a thermal dissociation of hydrogen chloride (HCl) reacted with ozone (O₃), the oxidation rate to form the silicon oxide film becomes faster in the region where concentrations of chlorine radicals (Cl*) and hydrogen radicals (H*) are high. In the supplying method of source gases shown in FIG. 8A, the concentrations of chlorine radicals (Cl*) and hydrogen radicals (H*) mentioned above become maximum at the center portion of the semiconductor substrate (semiconductor wafer). Therefore, the thickness of the silicon oxide film has a convexed form distribution having the maximum value at the center portion of the semiconductor substrate. On the other hand, in the supplying method of source gases shown in FIG. 8B, the film thickness uniformity of the silicon oxide film on the semiconductor substrate is dramatically improved because the concentrations of chlorine radicals (Cl*) and hydrogen radicals (H*) become uniform concentration distributions on the semiconductor substrate (semiconductor wafer). In other words, by providing a plurality of the introduction tubes for introducing ozone (O₃) and a plurality of the introduction tubes for introducing hydrogen chloride (HCl) alternately, the ozone concentration, the concentration of chlorine radicals (Cl*), and the concentration of hydrogen radicals (H*) on the semiconductor substrate can be uniform on the semiconductor substrate. As a result, the film thickness uniformity of the formed silicon oxide film can be improved over the whole surface of the semiconductor substrate.

While the example of introducing the source gases from total of nine positions including the four introduction tubes for supplying ozone (O₃) and the five introduction tubes for supplying hydrogen chloride (HCl) has been described in the second embodiment as illustrated in FIG. 8B, it has been revealed that the film thickness uniformity of the silicon oxide film formed on the semiconductor substrate can be ensured by flowing hydrogen chloride (HCl) simultaneously with a carrier gas such as argon (Ar) even when the number of the introduction positions of source gas is reduced. However, in the case where the number of introduction positions were less than or equal to five, the film thickness uniformity of the silicon oxide film formed on the silicon substrate was degraded. Therefore, as for the supply of source gases, it is can be understood that the source gases are preferred to be introduced from at least five or more positions.

While the example of carrying out the thermal oxidation method by flowing the source gases from one side of the sidewall portion of the semiconductor substrate (semiconductor wafer) to the other side of the sidewall portion has been described in the second embodiment, a supplying method of source gases of a shower head system as described in the following can be also used.

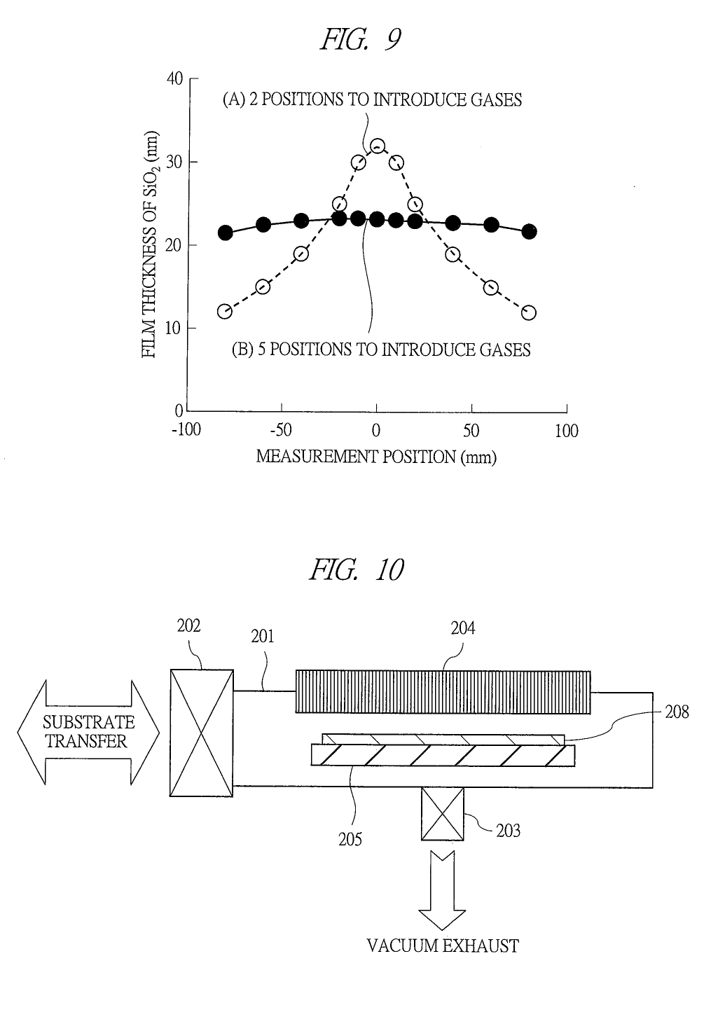

FIG. 10 is a diagram illustrating a thermal oxidation apparatus (oxidation apparatus) of a heater heating system. Though omitted in FIG. 10, it is structured such that a substrate transfer chamber is installed on the left side of FIG. 10 so that a semiconductor substrate 208 can be introduced into or discharged from a reaction chamber 201 via a gate bulb 202. The semiconductor substrate 208 is arranged on a susceptor 205 capable of performing a heater heating, and source gases are supplied from a shower head 204 installed to face the susceptor 205. Vacuum exhaust is made from a lower portion of the susceptor 205 via an exhaust bulb 203.

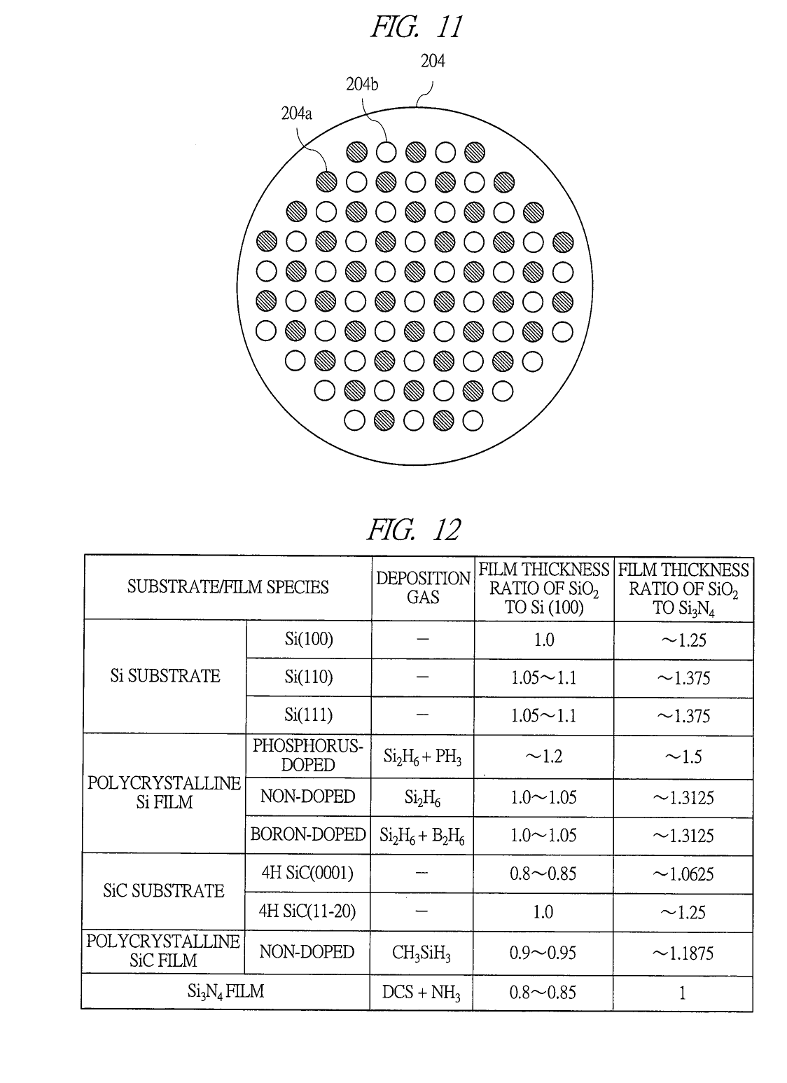

FIG. 11 is a diagram illustrating an arrangement of gas supply holes of the shower head 204. Gas supply holes 204a for supplying ozone (O₃) and gas supply holes 204b for supplying a catalyst gas (for example, hydrogen chloride (HCl)) are alternately arranged. As described above, in the case of carrying out the thermal oxidation method with supplying source gases (ozone (O₃) and catalyst gas) from the shower head 204, the ozone concentration, the concentration of chlorine radicals (Cl*), and the concentration of hydrogen radicals (H*) on the semiconductor substrate can be uniform on the semiconductor substrate by alternately arranging the gas supply holes 204a for supplying ozone (O₃) and the gas supply holes 204b for supplying the catalyst gas (for example, hydrogen chloride (HCl)). As a result, the film thickness uniformity of the formed silicon oxide film can be improved over the whole surface of the semiconductor substrate.

As described in the foregoing, the concentrations of ozone and the catalyst gas supplied onto the semiconductor substrate can be uniform over the whole surface of the semiconductor substrate in both of the heat treatment apparatus (oxidation apparatus) having the configuration shown in FIG. 1 and the heat treatment apparatus (oxidation apparatus) having the configuration shown in FIG. 10 by alternately providing a plurality of paths for supplying ozone (O₃) onto the semiconductor substrate and a plurality of paths for supplying a catalyst gas such as hydrogen chloride (HCl) onto the semiconductor substrate. As a result, the film thickness uniformity of the silicon oxide film formed on the whole surface of the semiconductor substrate can be improved.

### Third Embodiment

In the following, a thermal oxidation method according to a third embodiment will be described in detail with reference to the accompanied drawings. In the third embodiment, a single silicon substrate (resistivity: 10 Ω·cm) and a SiC substrate (4H) each having different orientations and a polycrystalline silicon film, a non-doped polycrystalline SiC film and a silicon nitride film (Si₃N₄ film) each having different impurities were prepared and each substrate or each thin film was oxidized in the same conditions, and a film thickness ratio of a silicon oxide film obtained thereby was evaluated.

The polycrystalline silicon film was formed by depositing a noncrystalline silicon film by a low pressure CVD (Chemical Vapor Deposition) method using disilane (Si₂H₆) as a source gas and then crystallizing the noncrystalline silicon film by a heat treatment. Disilane (Si₂H₆) and phosphine (PH₃) were used for a phosphorus-doped noncrystalline silicon film, and disilane (Si₂H₆) and diborane (B₂H₆) were used for a boron-doped noncrystalline silicon film. On the other hand, the non-doped noncrystalline silicon film was deposited with only disilane (Si₂H₆). Concentrations of phosphorus (P) and boron (B) in the noncrystalline silicon film was set to 5×10²⁰/cm³ Crystallization of the noncrystalline silicon film was performed by a nitrogen annealing in the conditions of a heat treatment temperature of 950° C. and a heat treatment time of 2 minutes. As the silicon carbide film (SiC film), a polycrystalline SiC film was formed by using a low pressure CVD method using monomethylsilane (CH₃SiH₃) as its source gas. The silicon nitride film was deposited by a low pressure CVD method using dichlorosilane (DCS: SiH₂Cl₂) and ammonia (NH₃) as its source gases. Any of these thin films was deposited to have a film thickness of 200 nm on the silicon substrate.

In the third embodiment, film thicknesses of the silicon oxide films obtained by oxidizing the above-mentioned respective substrates and respective thin films in the same conditions were observed by a transmission electron microscope (TEM), and these are shown as film thickness ratios to a film thickness of a silicon oxide film formed on the Si (100) substrate. The result of the observation is shown in FIG. 12. 90% of ozone (O₃) and hydrogen chloride (HCl) were used for the source gases of the oxidation processing, and the HCl concentration was set to 3.5%. In oxidation processings of a Si substrate (silicon substrate) and polycrystalline silicon films having different impurities using the dry oxidation method and wet oxidation method by normal oxygen (O₂), the film thickness of the formed silicon oxide film greatly differs depending on the orientation of the substrate and impurity concentration. For example, in the dry oxidation method with an oxidation temperature of 800° C., when oxidation processings are performed on the single crystal silicon substrate of Si(100) and the phosphorus-doped polycrystalline silicon film (phosphorus concentration=5×10²⁰/cm³), the silicon oxide film formed on the phosphorus-doped polycrystalline silicon film has a film thickness about four times thicker than that of the silicon oxide film formed on the single crystal silicon substrate of Si(100). In addition, little oxidation is developed on the SiC substrate (4H, SiC(0001)), the polycrystalline SiC film, the silicon nitride film etc., and the silicon oxide is not formed. On the contrary, in the thermal oxidation method according to the third embodiment, a film thickness ratio of the silicon oxide film formed on each of the above-mentioned substrates and each of the thin films to the silicon oxide film formed on the single crystal silicon substrate of Si(100) is in the range of 0.8 to 1.1, and it has thus been found that the thermal oxidation method according to the third embodiment gets little influence of the base.

In other words, in the case of carrying out the thermal oxidation method according to the third embodiment on respective substrates and respective thin films, it has been found that there is a difference of only 1.5 times at a maximum in the thickness of the silicon oxide film for the materials (bases) shown in FIG. 12 as referring to the film thickness of the silicon oxide film having the smallest thickness on the silicon nitride film.

Generally, it has been known that the thickness of the silicon oxide film obtained by oxidation has a small dependency on the base in the oxidation processing using oxygen radicals (O*), and the thermal oxidation method according to the third embodiment also indicates that the oxidation processing is advanced by oxygen radicals (O*).

As described in the foregoing, since it is possible to make influences from the orientation of the base small when forming a silicon oxide film on a silicon substrate or a SiC substrate by subjecting the silicon substrate or the SiC substrate to a thermal oxidation processing, a silicon oxide film having an almost uniform thickness can be formed even in a place where a plurality of orientations exist, such as an uneven portion of a pattern. For example, as a result of examining a breakdown voltage of an MIM (Metal Insulator Metal) capacitor formed of a stacked structure of silicon substrate/silicon oxide film/aluminum film formed by subjecting a silicon substrate and a SiC substrate having an unevenness on the base to the oxidization processing, the breakdown voltage of the MIM capacitor of the third embodiment was dramatically improved as compared with an MIM capacitor with a silicon oxide film formed by the conventional dry oxidation using oxygen (O₂) or the conventional wet oxidation using water vapor (H₂O). This result has been led by characteristic properties of the thermal oxidation method according to the third embodiment that it is possible to form a silicon oxide film having a uniform film thickness independent of influences of a base.

In addition, a difference between the thermal oxidation method of the third embodiment and the conventional thermal oxidation method using radicals is that the silicon oxide film formed by the conventional thermal oxidation method using radicals does not contain halogen elements and the silicon oxide film formed by the thermal oxidation method of the third embodiment contains halogen elements in contrast. Since halogen elements are taken into a part of the Si—O network when halogen elements are contained in the silicon oxide film, the more halogen elements are contained in the silicon oxide film, the lower the film density of the silicon oxide film becomes. That is, if the physical thickness is the same, the relative permittivity of the silicon oxide film is changed corresponding to the film density. Therefore, according to the third embodiment, the concentration of halogen elements in the silicon oxide film can be controlled in accordance with the places and purposes to apply the thermal oxidation processing. For example, the relative permittivity of the silicon oxide film is lowered by making the concentration of halogen elements contained in the silicon oxide film higher even with the same physical thickness, so that a silicon oxide film having an electrically large thickness can be formed. On the other hand, when a silicon oxide film having an electrically small thickness (having a large relative permittivity) is required, it can be solved by making the concentration of halogen elements small. In this manner, since the halogen-containing compound gas is used in a part of the source gases, the formed silicon oxide film contains halogen elements. Accordingly, by adjusting the concentration of the compound gas containing a halogen element composing a part of the source gases, the concentration of the halogen elements contained in the silicon oxide film can be adjusted. As a result, the thermal oxidation method according to the third embodiment has an advantage of being capable of forming silicon oxide films having different relative permittivities in accordance with the places and purposes to form the silicon oxide film.

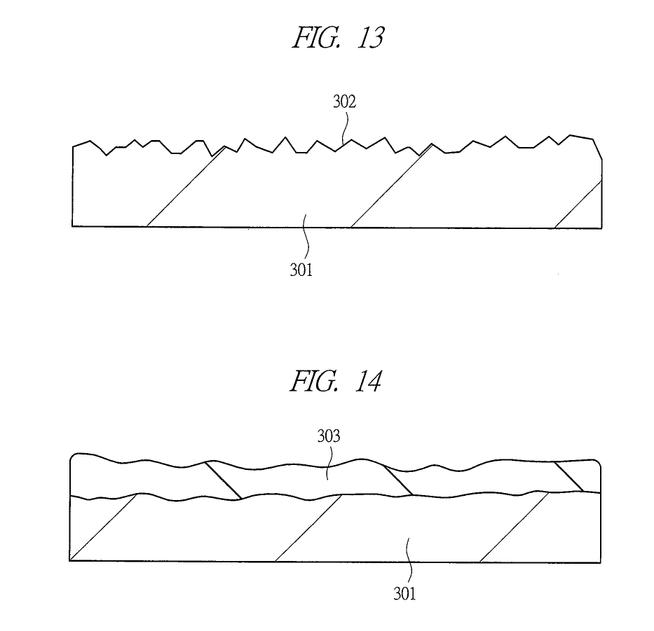

On the other hand, the thermal oxidation method of the third embodiment capable of forming a silicon oxide film independent of a base can be applied to the following example. FIG. 13 is a diagram illustrating an example where the thermal oxidation method of the third embodiment is adopted. In a manufacture of power devices using the SiC substrate, a heat treatment at about 1800° C. is required to activate impurities such as nitrogen introduced in the SiC substrate. Since silicon (Si) is sublimed from the SiC substrate in this high-temperature processing, a very large irregular form 302 is formed on a surface of a SiC substrate 301 as shown in FIG. 13. As one method for planarizing the irregular form 302 formed on the surface of the SiC substrate 301, a generally used method is such that a thick silicon oxide film 303 is formed on the surface of the SiC substrate 301, on which the irregular form 302 is formed, by using the dry oxidation method using oxygen (O₂) and the like (FIG. 14), and the silicon oxide film 303 is removed by hydrofluoric acid (FIG. 15). However, the dry oxidation method using oxygen (O₂) has a very small effect of mitigating the irregular form 302 because the oxidation rate to form the silicon oxide film has an orientation dependency. More specifically, since planes of various orientations are exposed on the irregular form 302, the normal dry oxidation method is difficult to form a silicon oxide film being uniform over the whole surface of the irregular form 302. On the contrary, when the thermal oxidation method according to the third embodiment is applied, a silicon oxide film having a uniform film thickness can be formed onto the irregular form 302 because the oxidation rate (film-formation rate) of the silicon oxide is less influenced by the form and orientations of the base. Therefore, the third embodiment has a significant feature of greatly enhancing the effect of mitigating the irregular form 302. Moreover, since the oxidation rate (film-formation rate) is high in the thermal oxidation method of the third embodiment, throughput can be also improved. Note that, while the example of the SiC substrate has been described in the third embodiment, the same effects can be obtained by a normal silicon substrate because the principle is the same.

### Fourth Embodiment

Next, a method of manufacturing a semiconductor device using a thermal oxidation method according to a fourth embodiment will be described in detail with reference to the accompanied drawings. In the fourth embodiment, an example where the thermal oxidation method of the fourth embodiment is applied to a formation of a thick thermal oxidation film (silicon oxide film) that is difficult to be formed by oxidation apparatuses (heat treatment apparatuses) of the wafer-by-wafer system and to a formation of a gate insulating film of a transistor will be described.

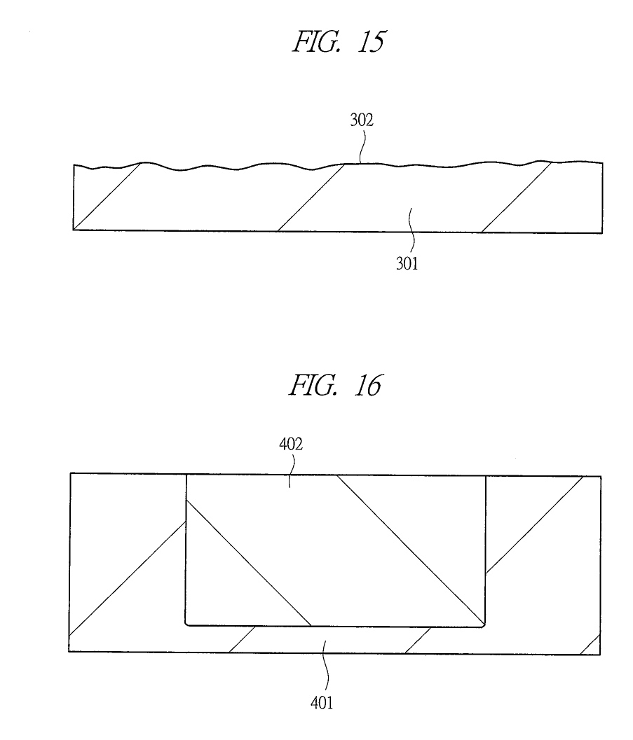

FIG. 16 to FIG. 26 illustrate a manufacturing process of an n-channel MISFET (Metal Insulator Semiconductor Field Effect Transistor). In the fourth embodiment, the n-channel MISFETs are simultaneously formed with taking a gate length (L) and a gate width (W) as parameters so that a gate length dependency and a gate width dependency of the threshold voltage can be evaluated.

First, as shown in FIG. 16, a p-type well 402 is formed on a semiconductor substrate 401 formed of p-type single crystal silicon in which a concentration of boron (B) is set to 1×10¹⁷/cm³. The p-type well 402 is formed by introducing a p-type impurity such as boron (B) to the semiconductor substrate 401 using, for example, an ion implantation method.

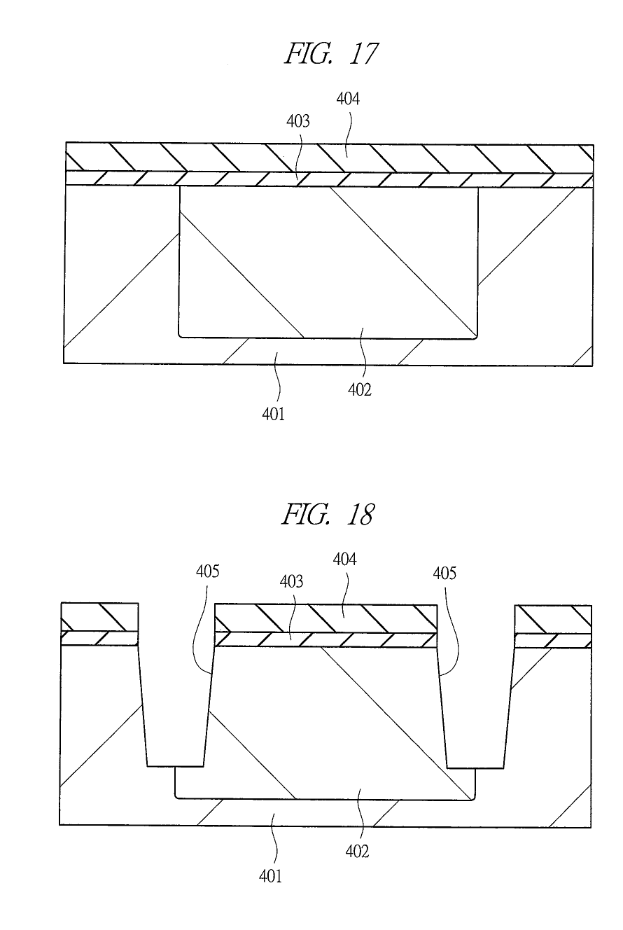

Subsequently, as shown in FIG. 17, a silicon oxide film 403 having a thickness of 10 nm and a silicon nitride film 404 having a thickness of 100 nm are sequentially formed on the semiconductor substrate 401. Here, in the formation of the silicon oxide film 403, an ISSG (In-Situ Steam Generation) oxidation method using oxygen (O₂) and hydrogen (H₂) is used, and as the conditions thereof, an oxidation temperature (heat treatment temperature) is set to 1000° C. and a hydrogen concentration is set to 33%. The silicon nitride film 404 is formed by a low-pressure CVD using monosilane (SiH₄) and ammonium (NH₃) as its source gases in a condition of a heat treatment temperature of 700° C.

Next, as illustrated in FIG. 18, the silicon nitride film 404, the silicon oxide film 403, and the semiconductor substrate 401 are sequentially etched by a photolithography technique and a dry etching technique. In this manner, trenches 405 for device isolation are formed in the semiconductor substrate 401. A depth of the trench 405 is, for example, 300 nm.

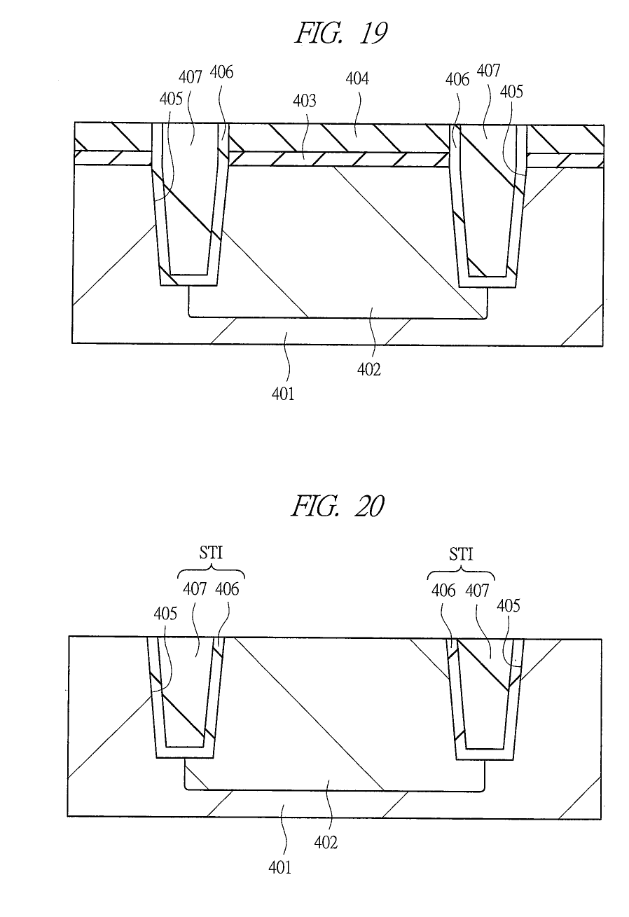

Subsequently, as illustrated in FIG. 19, an oxidation processing is performed on an inner wall of the trench 405 by using the thermal oxidation method of the fourth embodiment, thereby forming a silicon oxide film 406 on the silicon nitride film 404 including the inner wall of the trench 405. Here, 90% of ozone (O₃) and hydrogen chloride (HCl) are used as oxidizing gases. Then, the silicon oxide film 406 having a thickness of 20 nm is formed in conditions of an oxidation temperature (heat treatment temperature) of 900° C. and a HCl concentration of 3.5%.

As described in the third embodiment above, since the oxidation rate (film-formation rate) of the silicon oxide film has little dependency on orientations of the base, the silicon oxide film 406 with the same thickness is formed also on a bottom portion, sidewalls, and corner portions of the trench 405. In addition, according to the thermal oxidation method of the fourth embodiment, the silicon oxide film 406 is formed also on sidewall portions and a surface of the patterned silicon nitride film 404 because the film-formation rate of the silicon oxide film 406 formed on a silicon nitride film is also high. Note that, as described above in the first embodiment and so forth, halogen elements are contained in the silicon oxide film 406.

While the silicon oxide film 406 is formed on a surface of the semiconductor substrate 401, an ISSG oxidation method is used for forming the silicon oxide film 406 in the fourth embodiment. The ISSG oxidation method employs the lamp heating method which is generally suitable for short-time processing. Accordingly, it can be considered to use the ISSG oxidation method also for the silicon oxide film 406 formed on the inner wall of the trench 405. However, in the case of forming the silicon oxide film 406 by performing an oxidation processing on the inner wall of the trench 405, since the silicon oxide film 406 is required to be formed thick to have a thickness exceeding 20 nm, three minutes or more of time is required at 1000° C. when the above-mentioned ISSG oxidation method is used. Meanwhile, since the lamp heating method suitable for short-time heating is generally employed in the ISSG oxidation method, it is difficult to adopt the ISSG oxidation method for an oxidation processing with a high temperature and a long time, that is, at 1000° C. and for three minutes or longer in terms of the apparatus configuration. Therefore, the heater heating oxidation method of the batch system is often adopted to form a silicon oxide film having a large thickness like the silicon oxide film 406. In the case of using the heater heating oxidation method of the batch system, there is the possibility that the impurities of the p-type well 402 formed in an earlier step than the silicon oxide film 406 are diffused because of the high temperature and the long heat treatment time and an impurity profile is changed. Then, it leads to malfunctions such as a variation in electric characteristics of manufactured MISFETs differing in every device. Further, the batch system has a problem of lowering throughput.

Accordingly, in the fourth embodiment, the thermal oxidation method using ozone (O₃) and hydrogen chloride (HCl) as its source gases is used as a method of forming the silicon oxide film 406 as thick as about 20 nm. According to this thermal oxidation method of the fourth embodiment, decomposition of ozone is accelerated by the catalyst function of chlorine radicals (Cl*) and hydrogen radicals (H*) formed by the thermal dissociation of hydrogen chloride (HCl). In other words, according to the thermal oxidation method of the fourth embodiment, a large amount of oxygen radicals (O*) are generated by decomposing ozone (O₃), thereby generating the enhanced-rate oxidation phenomenon. Since the enhanced-rate oxidation phenomenon is generated at a temperature at which hydrogen chloride is thermally dissociated, it can be achieved at a temperature lower than 1000° C. Furthermore, the film-formation rate of the silicon oxide film becomes faster because the enhanced-rate oxidation phenomenon is generated, so that the oxidation processing can be performed in a shorter time than the conventional techniques such as the ISSG oxidation method and the heater heating oxidation method of a batch system. In this manner, according to the thermal oxidation method of the fourth embodiment, the thick silicon oxide film 406 can be formed at a low temperature and in a short time. Consequently, since diffusion of impurities introduced in the p-type well 402 can be suppressed, and at the same time, the oxidation process can be done by an oxidation apparatus (heat treatment apparatus) of wafer-by-wafer system, the throughput can be improved.

Subsequently, as illustrated in FIG. 19, a silicon oxide film 407 is deposited by using a high-density plasma CVD so that the silicon oxide film 407 is buried in the trenches 405. After that, the silicon oxide film 407 and the silicon oxide film 406 are scraped by CMP (Chemical Mechanical Polishing) so that the surface of the semiconductor substrate 401 is planarized. In this polishing, a part of the silicon nitride film 404 is also polished.

Next, as illustrated in FIG. 20, after the patterned silicon nitride film 404 is removed by heated phosphoric acid (hot phosphoric acid), the silicon oxide film 403 is removed by dilute hydrofluoric acid, thereby exposing the surface of the semiconductor substrate 401. In the process as thus far described, device isolation regions STI in which the silicon oxide film 406 and the silicon oxide film 407 are buried in the trenches 405 are formed.

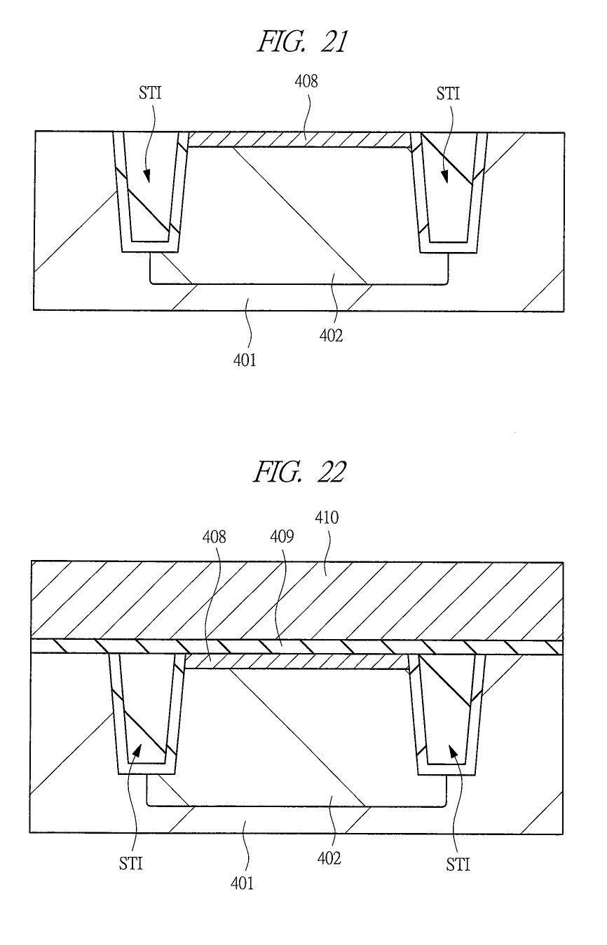

Subsequently, as illustrated in FIG. 21, boron (B) for adjusting a threshold voltage to a predetermined voltage is ion-implanted in a vicinity of the surface of the semiconductor substrate 401 isolated by the device isolation regions STI. In this manner, a semiconductor region for threshold voltage adjustment 408 is formed in the vicinity of the surface of the semiconductor substrate 401. Then, cleaning of the semiconductor substrate 401 is carried out in known methods.

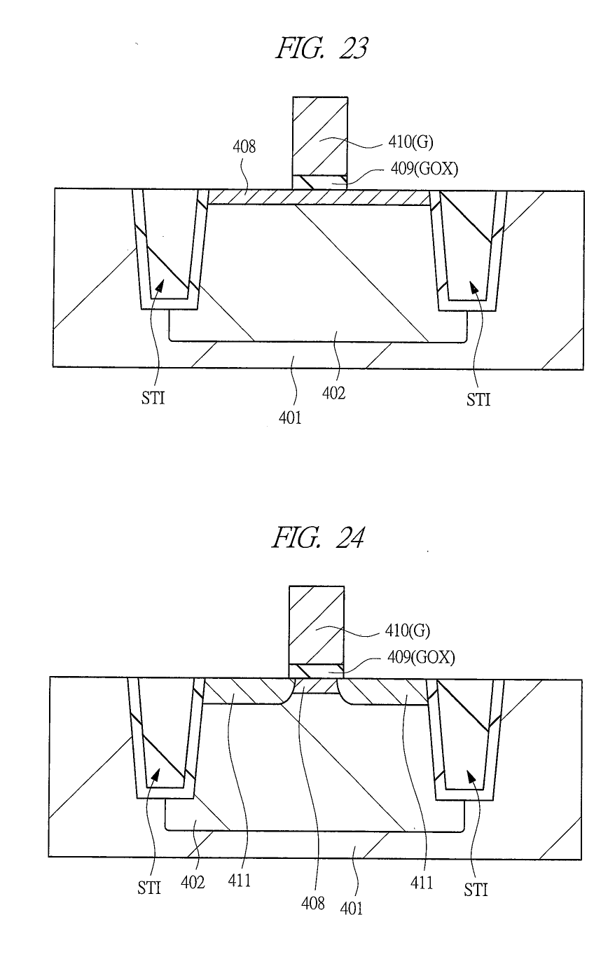

After that, as illustrated in FIG. 22, a silicon oxide film 409 is formed on the semiconductor substrate 401. At this time, the silicon oxide film 409 is formed by the thermal oxidation method of the fourth embodiment for a sample X. More specifically, the silicon oxide film 409 is formed to have a thickness of 7 nm by the thermal oxidation method using ozone (O₃) and hydrogen chloride (HCl). On the other hand, the silicon oxide film 409 is formed to have a thickness of 7 nm by the ISSG oxidation method for a sample Y. Herein, while the silicon oxide film 409 of the sample X is formed at a temperature of 700° C., the silicon oxide film 409 of the sample Y is formed at a temperature of 900° C. Note that the oxidation times for both of the sample X and sample Y are the same.

Subsequently, a polysilicon film 410 to which phosphorus is introduced is formed on the silicon oxide film 409. The polysilicon film 410 can be formed by using, for example, a CVD method. Then, as illustrated in FIG. 23, the polysilicon film 410 and the silicon oxide film 409 are processed by an etching using a patterned resist film as a mask, thereby forming a gate electrode G formed of the polysilicon film 410 and a gate insulating film GOX formed of the silicon oxide film 409.

Then, as illustrated in FIG. 24, by using a photolithography technique and an ion-implantation method, shallow n-type impurity diffusion regions 411 aligned with the gate electrode G are formed. The shallow n-type impurity diffusion regions 411 are semiconductor regions.

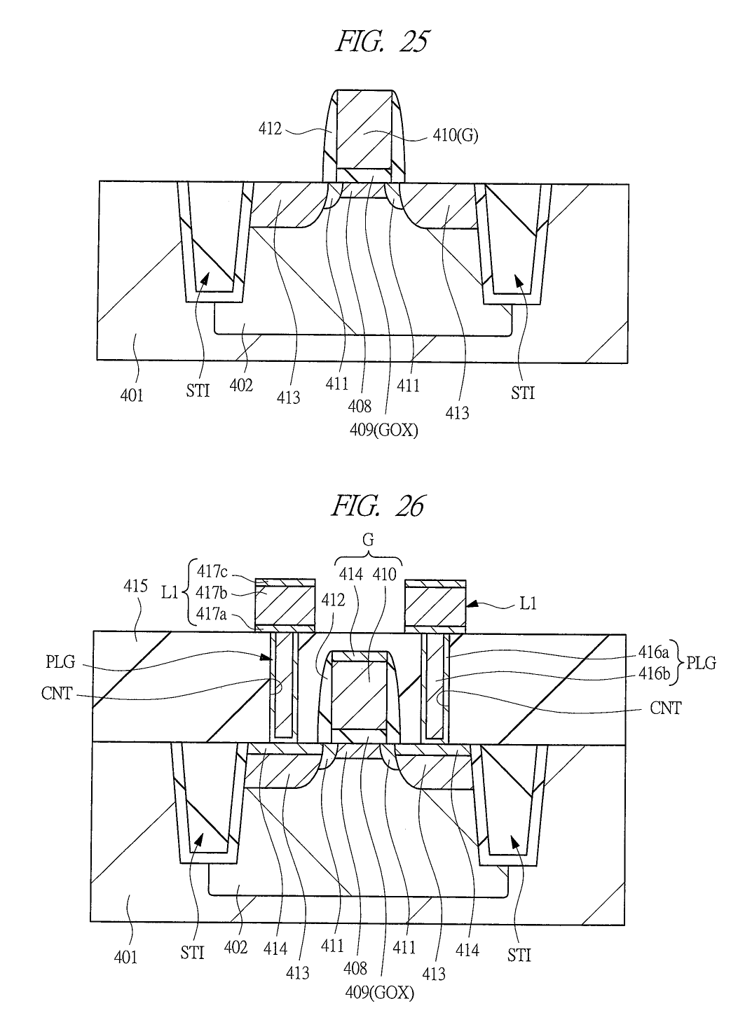

Next, as illustrated in FIG. 25, a silicon oxide film is formed on the semiconductor substrate 401. The silicon oxide film can be formed by using, for example, a CVD method. Then, by subjecting the silicon oxide film to an anisotropic etching, sidewalls 412 are formed on sidewalls of the gate electrode G. While the sidewall 412 is formed of a single-layer film of a silicon oxide film, it is not limited to this and sidewalls formed of a stacked film of a silicon nitride film and a silicon oxide film may be formed.

Subsequently, by using a photolithography technique and an ion-implantation method, deep n-type impurity diffusion regions 413 which are aligned with the sidewalls 412 are formed. The deep n-type impurity diffusion regions 413 are semiconductor regions. The deep n-type impurity diffusion region 413 and the shallow n-type impurity diffusion region 411 form a source region. Similarly, the deep n-type impurity diffusion region 413 and the shallow n-type impurity diffusion region 411 form a drain region. By forming the source region and drain region by the deep n-type impurity diffusion regions 413 and the shallow n-type impurity diffusion regions 411 in this manner, the source region and drain region can be formed to have an LDD (Lightly Doped Drain) structure.

After forming the deep n-type impurity diffusion regions 413 in this manner, a heat treatment is performed. More specifically, a heat treatment at 1250° C. for 800 microseconds is performed by carbon dioxide laser annealing, so that the impurities introduced in the deep n-type impurity diffusion regions 413 are activated.

Thereafter, as illustrated in FIG. 26, a cobalt film is formed on the semiconductor substrate 401. At this time, the cobalt film is formed to be in a direct contact with the gate electrode G. Similarly, the cobalt film is in a direct contact with the deep n-type impurity diffusion regions 413.

The cobalt film can be formed by using, for example, sputtering. Then, by performing a heat treatment after forming the cobalt film, the polysilicon film 410 and the cobalt film forming the gate electrode G are reacted, thereby forming a cobalt silicide film 414. Consequently, the gate electrode G has a stacked structure of the polysilicon film 410 and the cobalt silicide film 414. The cobalt silicide film 414 is formed for lowering a resistance of the gate electrode G. Similarly, by the heat treatment described above, silicon and the cobalt film are reacted and the cobalt silicide film 414 is formed also on a surface of the deep n-type impurity diffusion regions 413. Therefore, a resistance lowering can be made also in the deep n-type impurity diffusion regions 413.

Then, the unreacted cobalt film is removed from the semiconductor substrate 401. Note that, while it is configured to form the cobalt silicide film 414 in the fourth embodiment, for example, a nickel silicide film or a titanium silicide film may be formed instead of the cobalt silicide film 414.

Next, a silicon oxide film 415 to be an interlayer insulating film is formed on a main surface of the semiconductor substrate 401. This silicon oxide film 415 can be formed by using, for example, a CVD method using TEOS (tetra ethyl ortho silicate) as its material. After that, a surface of the silicon oxide film 415 is planarized by using, for example, a CMP method.

Subsequently, by using a photolithography technique and an etching technique, contact holes CNT are formed in the silicon oxide film 415. Then, a titanium/titanium-nitride film 416a is formed on the silicon oxide film 415 including a bottom surface and inner walls of the contact hole CNT. The titanium/titanium-nitride film 416a is formed of a stacked film of a titanium film and a titanium nitride film, and it can be formed by using, for example, sputtering. This titanium/titanium-nitride film 416a has a so-called barrier property for preventing tungsten that is a material of a film to be buried in a later step from being diffused into silicon.

Subsequently, a tungsten film 416b is formed on the whole main surface of the semiconductor substrate 401 so as to bury the contact holes CNT. This tungsten film 416b can be formed by using, for example, a CVD method. Then, by removing unnecessary part of the titanium/titanium-nitride film 416a formed on the silicon oxide film 415 and the tungsten film 416b by, for example, a CMP method, plugs PLG can be formed.

Next, a titanium/titanium-nitride film 417a, an aluminum film 417b containing copper, and a titanium/titanium-nitride film 417c are sequentially formed on the silicon oxide film 415 and the plugs PLG. These films can be formed by using, for example, a sputtering method. Subsequently, these films are patterned by using a photolithography technique and an etching technique, so that wirings L1 are formed. While wirings will be formed further for upper layers of the wirings L1, descriptions thereof will be omitted herein. In this manner, the semiconductor device according to the fourth embodiment can be formed.

As a result of the evaluations conducted on the sample X and the sample Y manufactured in the fourth embodiment, differences in threshold voltage have been observed in devices having small gate widths (W). Herein, the gate voltage which makes a drain current Id=10 nA under the conditions of a source voltage=0 V, a drain voltage=1 V, and a substrate voltage=0 V is defined as the threshold voltage. 256 pieces of n-channel MISFETs having the same device size of the sample X and sample Y were respectively measured, and variations (5 Sigma) in the threshold voltage were compared. As the result of the comparison, a variation of the threshold voltage of the sample X in which the silicon oxide film 409 to be a gate insulating film is formed by the thermal oxidation method of the fourth embodiment becomes as small as 85% of a variation of the threshold voltage of the sample Y in which the silicon oxide film 409 to be the gate insulating film is formed by the ISSG oxidation method. This is probably because, since the oxidation temperature of the silicon oxide film 409 of the sample X is lower than that of the sample Y and a change in the boron concentration of the threshold voltage adjustment semiconductor region 408 in a direct contact with the silicon oxide film 409 that is the gate insulating film is small, the concentration variation is decreased eventually. That is, the silicon oxide film 409 to be a gate insulating film can be formed at a low temperature and in a short time according to the thermal oxidation method of the fourth embodiment. Therefore, diffusion of impurities in the threshold voltage adjustment semiconductor region 408 formed in an earlier step than the silicon oxide film 409 can be suppressed. Accordingly, a concentration variation of impurities in the threshold voltage adjustment semiconductor region 408 can be suppressed.

In addition, the sample X and the sample Y were compared also regarding hot-carrier resistance that indicates superiority in reliability of transistors. For example, a current is continuously flowed into the n-channel MISFET in the measurement conditions with a large hot-carrier injection efficiency, and temporal changes in a drain current (Id) at a certain gate voltage (Vg) are compared. In other words, the threshold voltage is gradually increased as carriers are trapped into the gate insulating film. Thus, by observing the phenomenon of a decrease in the drain current (Id) in a state where the certain gate voltage (Vg) is being applied, the hot-carrier resistance in the MISFET can be measured. For example, it can be understood that the hot-carrier resistance is good when a decrease of the drain current (Id) is small, and it is can be understood that the hot-carrier resistance is deteriorated when a decrease of the drain current (Id) is large on the other hand. As a result, it has been revealed that the sample X has an improved hot-carrier resistance than the sample Y. This is because chlorine elements (Cl) are present in an interface of the semiconductor substrate 401 and the silicon oxide film 409 to be the gate insulating film in the fourth embodiment. In this manner, in the fourth embodiment, an improvement in the hot-carrier resistance that is an advantage of the long-known HCl oxidation using oxygen (O₂) and hydrogen chloride (HCl) has been also confirmed. However, while the conventional HCl oxidation has a substrate orientation dependency in the oxidation rate (film-formation rate) of the silicon oxide film like in the normal dry oxidation using oxygen (O₂), the thermal oxidation method of the fourth embodiment has also the feature of not having a substrate orientation dependency in the oxidation rate (film-formation rate) like the radical oxidation method.

As described in the foregoing, since thermal load along with a formation of a thermal oxidation film (silicon oxide film) can be reduced according to the fourth embodiment, variations in the threshold voltage can be suppressed. In addition, since it is possible to introduce halogen elements in an interface of the semiconductor substrate, the hot-carrier resistance of MISFET can be improved. Further, since there is almost no substrate orientation dependency in the oxidation rate (film-formation rate), the application to the three-dimensional devices is also possible. Moreover, since the process can be carried out in a short time according to the thermal oxidation method of the fourth embodiment, oxidation can be carried out by an oxidation apparatus of not only the batch system but also the wafer-by-wafer system. Therefore, according to the thermal oxidation method of the fourth embodiment, throughput can be also improved.

Note that the measurement voltage conditions and the absolute values of thicknesses of thin films described in the fourth embodiment are just examples, and the present invention is not limited by these numerical values.

### Fifth Embodiment

Next, a fifth embodiment will be described with reference to accompanied drawings. In the fifth embodiment, an example of applying the present invention to a manufacture of a MONOS memory transistor that is one of nonvolatile memories will be described.

There is a MONOS (Metal-Oxide-Nitride-Oxide-Semiconductor) memory as a typical example of a nonvolatile memory (nonvolatile semiconductor memory device) taking an insulating film as a memory node. The MONOS memory has a stacked structure of a conductive gate electrode (M), a silicon oxide film (second potential barrier film) (O), a silicon nitride film (charge accumulating film) (N), a silicon oxide film (first potential barrier film) (O), and a semiconductor substrate (S). The MONOS memory memorizes information by injecting or emitting carriers (charges) to or from the silicon nitride film having a charge retaining function.

A general method is such that the silicon oxide film (first potential barrier film) formed on a surface of the semiconductor substrate is formed by thermally oxidizing the semiconductor substrate, and the silicon oxide film (second potential barrier film) on the silicon nitride film is formed by thermally oxidizing the silicon nitride film. Herein, the silicon oxide film (first potential barrier film) to be formed at a lower layer of the silicon nitride film will be referred to as “a bottom Si oxide film,” and the silicon oxide film (second potential barrier film) to be formed at an upper layer of the silicon nitride film will be referred to as “a top Si oxide film.”

In the following, a method of manufacturing a MONOS memory (nonvolatile semiconductor memory device) according to the fifth embodiment will be described.

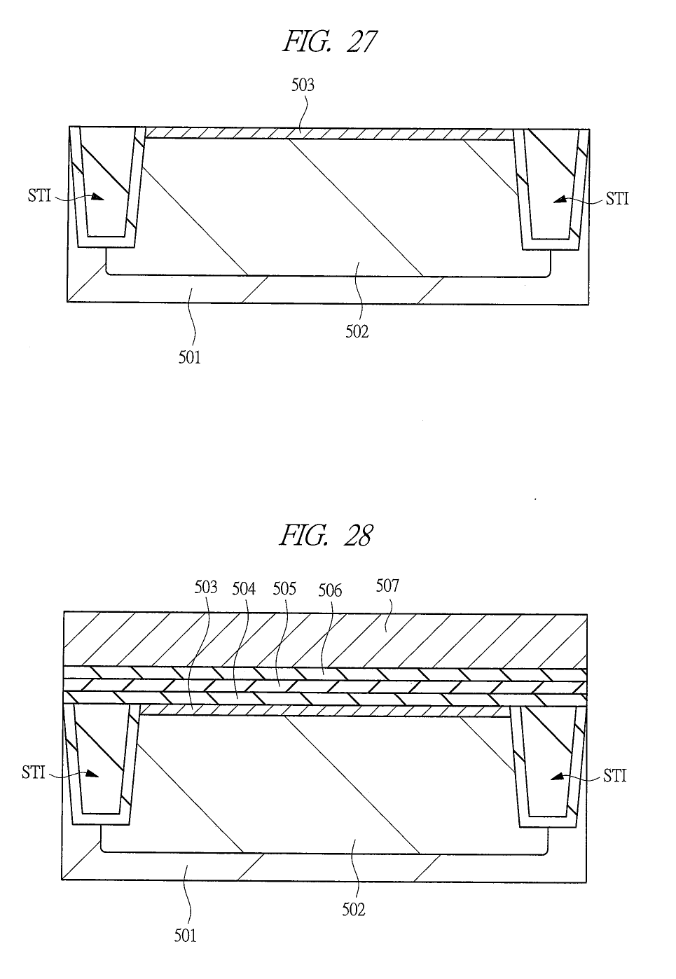

First, as illustrated in FIG. 27, a p-type well 502 is formed in a semiconductor substrate 501 by the same method as the method described in the fourth embodiment, and thereafter, trenches are formed in the semiconductor substrate 501. Then, a first silicon oxide film is formed on inner walls of the trenches, and a second silicon oxide film is formed so as to bury the trenches after forming the first silicon oxide film. In this manner, device isolation regions STI in which the first silicon oxide film and the second silicon oxide film are buried in the trenches are formed.

At this time, the first silicon film formed on the inner walls of the trench is formed by the thermal oxidation method of the fourth embodiment. Therefore, in the fifth embodiment, the first silicon oxide film having a large thickness can be formed at a low temperature and in a short time similarly to the fourth embodiment. Thus, as well as diffusion of impurities introduced in the p-type well 502 can be suppressed, the process can be performed by an oxidation apparatus of wafer-by-wafer system, and therefore, the throughput can be improved.

Next, as illustrated in FIG. 27, boron (B) for adjusting a threshold voltage to a predetermined voltage is ion-implanted into a vicinity of a surface of the semiconductor substrate 501. In this manner, threshold voltage adjustment semiconductor regions 503 are formed in the vicinity of the surface of the semiconductor substrate 501. Then, the semiconductor substrate is cleaned by known methods.

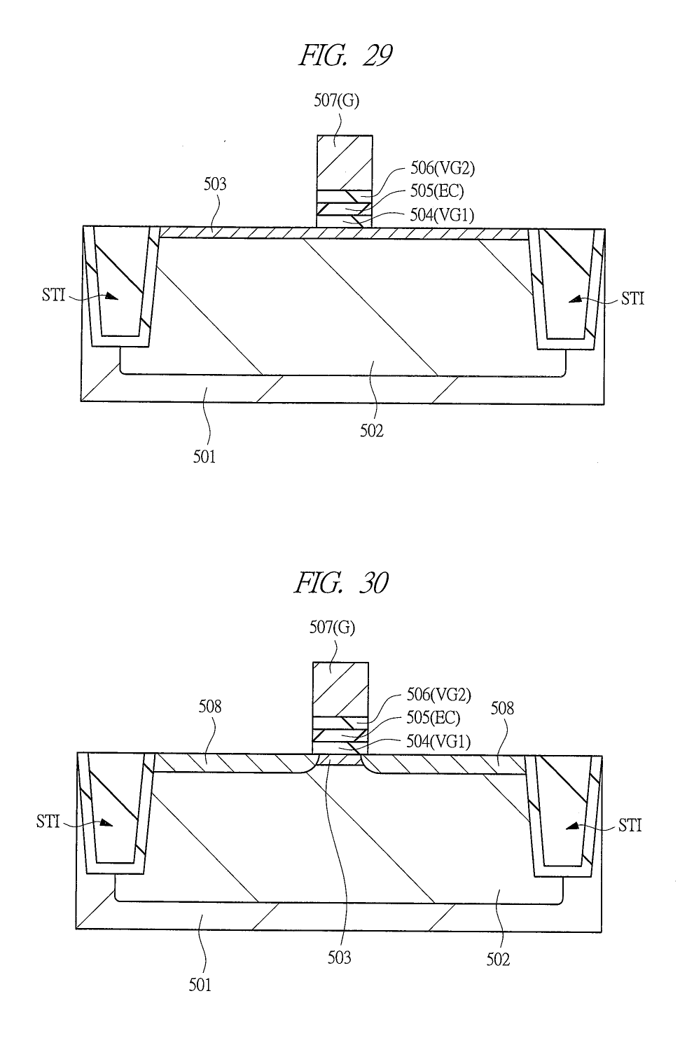

Subsequently, as illustrated in FIG. 28, for the sample X, a bottom Si oxide film 504 is formed to have a film thickness of 5 nm by the thermal oxidation method using ozone (O₃) and hydrogen chloride (HCl). On the other hand, for the sample Y, the bottom Si oxide film 504 is formed to have a film thickness of 5 nm by the ISSG oxidation method. Here, while the bottom Si oxide film 504 of the sample X is formed at a temperature of 700° C., the bottom Si oxide film 504 is formed at a temperature of 900° C. Note that the oxidation time is same for both of the sample X and the sample Y.

Next, a silicon nitride film 505 having a thickness of 15 nm is formed on the bottom Si oxide film 504 by a low-pressure CVD method using dichlorosilane (SiH₂Cl₂) and ammonia (NH₃) as its source gases. In the fifth embodiment, the silicon nitride film 505 is formed at a temperature of 650° C.

Thereafter, a top Si oxide film 506 having a thickness of 10 nm is formed on the silicon nitride film 505. At this time, for the sample X, the top Si oxide film 506 is formed by the thermal oxidation method using oxygen (O₂) and hydrogen chloride (HCl). On the other hand, for the sample Y, the top Si oxide film 506 is formed by the ISSG oxidation method. Here, while the top Si oxide film 506 of the sample X is formed at a temperature of 700° C., the top Si oxide film 506 of the sample Y is formed at a temperature of 1000° C. Note that the oxidation time is the same for both of the sample X and the sample Y.

Subsequently, a phosphorus-introduced polysilicon film 507 to be a gate electrode is formed by a low-pressure CVD method. At this time, a formation temperature of the polysilicon film 507 is 640° C.

Next, as illustrated in FIG. 29, by using a photolithography technique and a dry etching technique, the polysilicon film 507, the top Si oxide film 506, the silicon nitride film 505, and the bottom Si oxide film 504 are sequentially dry-etched. In this manner, a gate electrode G formed of the polysilicon film 507 is formed, and a second potential barrier film VG2 formed of the top Si oxide film 506 is formed. In addition, a charge accumulating film EC formed of the silicon nitride film 505 is formed, and a first potential barrier film VG1 formed of the bottom Si oxide film 504 is formed.

Thereafter, as illustrated in FIG. 30, by using a photolithography technique and an ion-implantation method, shallow n-type impurity diffusion regions 508 aligned with the gate electrode G are formed. The shallow n-type impurity diffusion region 508 is a semiconductor region.

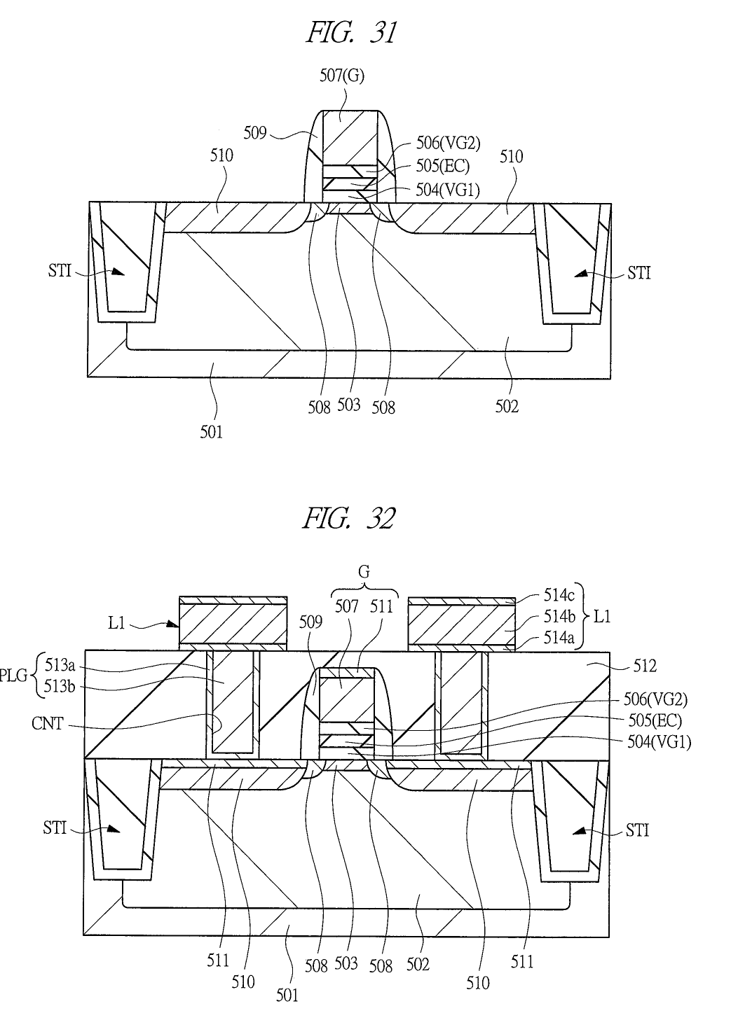

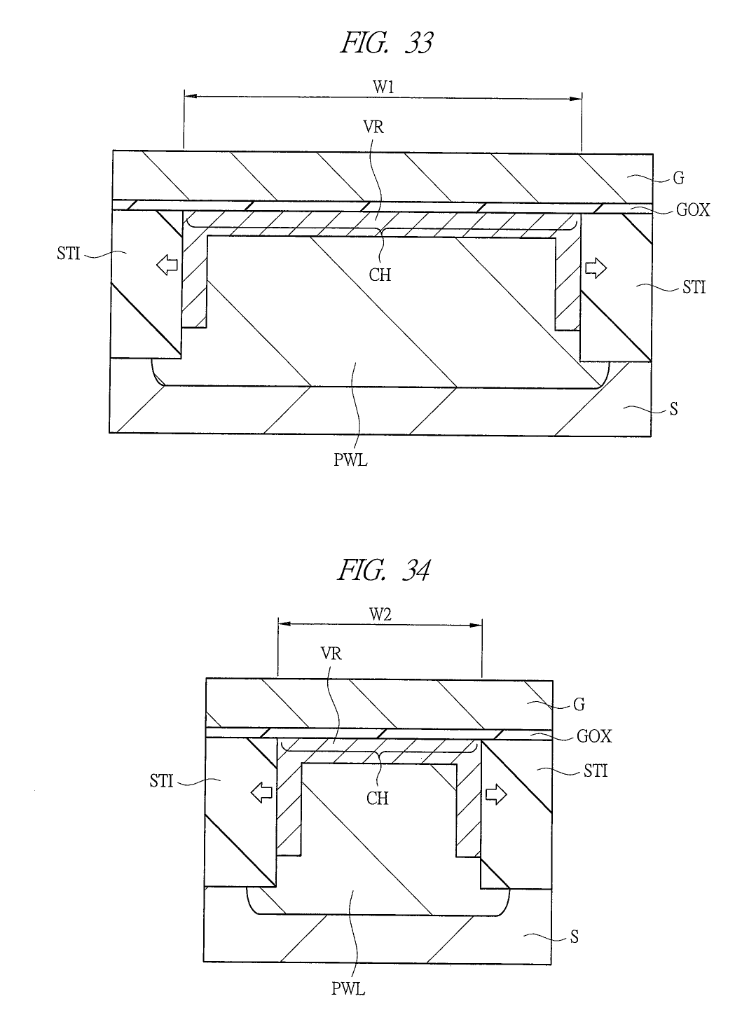

Next, as illustrated in FIG. 31, a silicon oxide film is formed on the semiconductor substrate 501. The silicon oxide film can be formed by using, for example, a CVD method. Then, by anisotropically etching the silicon oxide film, sidewalls 509 are formed on sidewalls of the gate electrode G. While the sidewall 509 is formed of a single-layered film of a silicon oxide film, it is not limited to this and the sidewall 509 can be formed of a stacked film of a silicon nitride film and a silicon oxide film.

Subsequently, by using a photolithography technique and an ion-implantation method, deep n-type impurity diffusion regions 510 aligned with the sidewalls 509 are formed. The deep n-type impurity diffusion region 510 is a semiconductor region. A source region is formed with the deep n-type impurity diffusion region 510 and the shallow n-type impurity diffusion region 508. Similarly, a drain region is formed with the deep n-type impurity diffusion region 510 and the shallow n-type impurity diffusion region 508. In this manner, by forming the source region and the drain region with the deep n-type impurity diffusion regions 510 and the shallow n-type impurity diffusion regions 508, the source region and drain region can be formed to have an LDD (Lightly Doped Drain) structure.

A heat treatment is performed after forming the deep n-type impurity diffusion regions 510 in this manner. More specifically, a heat treatment at 1250° C. for 800 microseconds is carried out by a carbon dioxide laser annealing, so that impurities introduced in the deep n-type impurity diffusion regions 510 are activated.

Thereafter, as illustrated in FIG. 32, a cobalt film is formed on the semiconductor substrate 501. At this time, the cobalt film is formed to be in a direct contact with the gate electrode G. Similarly, the cobalt film is in a direct contact with the deep n-type impurity diffusion regions 510.

The cobalt film can be formed by using, for example, sputtering. Then, by performing a heat treatment after forming the cobalt film, the polysilicon film 507 composing the gate electrode G and the cobalt film are reacted, so that a cobalt silicide film 511 is formed. In this manner, the gate electrode G has a stacked structure of the polysilicon film 507 and the cobalt silicide film 511. The cobalt silicide film 511 is formed for lowering a resistance of the gate electrode G. Similarly, by the above-mentioned heat treatment, silicon and the cobalt film are reacted also on a surface of the deep n-type impurity diffusion regions 510, so that the cobalt silicide film 511 is formed. Therefore, a reduction in resistance can be achieved also in the deep n-type impurity diffusion regions 510.

Then, the unreacted cobalt film is removed from the semiconductor substrate 501. Note that, while it has been configured to form the cobalt silicide film 511 in the fifth embodiment, for example, a nickel silicide film and a titanium silicide film can be formed instead of the cobalt silicide film 511.

Next, a silicon oxide film 512 to be an interlayer insulating film is formed on the main surface of the semiconductor substrate 501. This silicon oxide film 512 can be formed by using, for example, a CVD method using TEOS (tetra ethyl ortho silicate) as its material. Thereafter, a surface of the silicon oxide film 512 is planarized by using a CMP (Chemical Mechanical Polishing) method.

Subsequently, by using a photolithography technique and an etching technique, contact holes CNT are formed in the silicon oxide film 512. Then, a titanium/titanium nitride film 513a is formed on the silicon oxide film 512 including a bottom surface and inner walls of the contact hole CNT. The titanium/titanium nitride film 513a is formed of a stacked film of a titanium film and a titanium nitride film, and can be formed by using, for example, sputtering. This titanium/titanium nitride film 513a has a so-called barrier property for preventing tungsten that is a material of a film to be buried in a later step from being diffused into silicon.

Subsequently, a tungsten film 513b is formed on the whole surface of the main surface of the semiconductor substrate 501 so as to bury the contact holes CNT. This tungsten film 513b can be formed by using, for example, a CVD method. Then, unnecessary part of the titanium/titanium nitride film 513a and the tungsten film 513b formed on the silicon oxide film 512 are removed by, for example, a CMP method, thereby forming plugs PLG.

Next, a titanium/titanium nitride film 514a, an aluminum film 514b containing copper, and a titanium/titanium nitride film 514c are sequentially formed on the silicon oxide film 512 and the plugs PLG. These films can be formed by using, for example, sputtering. Subsequently, by using a photolithography technique and an etching technique, these films are patterned, so that a wiring L1 is formed. While wirings will be further formed for upper layers of the wiring L1, descriptions thereof will be omitted. In this manner, the semiconductor device of the fifth embodiment can be formed.

In evaluations on the sample X and the sample Y manufactured in the fifth embodiment, differences in threshold voltage were observed in devices having a small gate width (W). In the fifth embodiment, the gate voltage which makes a drain current Id=10 nA under the conditions of a source voltage=0 V, a drain voltage=1 V, and a substrate voltage=0 V is defined as the threshold voltage. 256 pieces of MONOS memory transistors having the same device size have been measured for both of the sample X and the sample Y, and variations in the threshold voltage (5 Sigma) has been compared. As a result, variations in the threshold voltage of the sample X in which the bottom Si oxide film 504 and the top Si oxide film 506 are formed by the thermal oxidation method of the fifth embodiment became small to be about 90% of variations in the threshold voltage of the sample Y in which the bottom Si oxide film 504 and the top Si oxide film 506 are formed by the ISSG method. This is probably because, since the oxidation temperature of the bottom Si oxide film 504 and the top Si oxide film 506 of the sample X is smaller than that of the sample Y, a change in the boron concentration of the threshold voltage adjustment semiconductor region 503 in contact with the bottom Si oxide film 504 is small. Particularly, a difference in the oxidation temperature of the top Si oxide film 506 formed on the silicon nitride film 505 that has a very low oxidation rate (film-formation rate) causes the large difference between the sample X and the sample Y. More specifically, in the case of forming the top Si oxide film 506 on the silicon nitride film 505 by using the normal ISSG method, since it is necessary to oxidize the silicon nitride film 505 having an anti-oxidation property, a high-temperature and long-time oxidation processing is required. Therefore, large thermal load is applied to the semiconductor substrate 501, so that the diffusion of boron introduced in the threshold voltage adjustment semiconductor region 503 becomes greater. On the contrary, in the thermal oxidation method of the fifth embodiment, a silicon oxide film with a fast oxidation rate can be formed without being influenced by its base. In other words, even when the base is the silicon nitride film 505, a top Si oxide film having a desired film thickness can be formed by a heat treatment at a low temperature and for a short time. Consequently, the thermal load applied to the semiconductor substrate 501 when forming the top Si oxide film 506 can be reduced, and diffusion of boron introduced in the threshold voltage adjustment semiconductor region 503 can be suppressed.

In addition, in a comparison of the sample X and the sample Y for a rewrite resistance, the sample X was improved in the rewrite resistance than the sample Y. This is because, as described in the fourth embodiment, chlorine elements (Cl) contained in the bottom Si oxide film 504 and the top Si oxide film 506 suppress the trapping of electrons in the silicon oxide film. In other words, in the fifth embodiment, by controlling the concentration of chlorine elements (Cl) in the silicon oxide film, it is possible to improve a hot-carrier resistance. Accordingly, by applying the thermal oxidation method of the fifth embodiment to a manufacture of the MONOS memory transistor in which electrons are put into and taken out from the silicon nitride film 505 through the bottom Si oxide film 504, the rewrite resistance of the manufactured MONOS memory transistor is improved. In other words, when the hot-carrier resistance is degraded, electrons are accumulated in the bottom Si oxide film 504. This means that the threshold voltage is increased, and as a result of the increase of the threshold voltage, a writing current is reduced, so that a writing time becomes long. This is a degradation of the rewrite resistance. Since the bottom Si oxide film 504 contains chlorine elements (Cl) in the fifth embodiment, charges to be trapped in the bottom Si oxide film 504 can be reduced. As the result of the improvement in the hot-carrier resistance enabled in this manner, the rewrite resistance of the MONOS memory transistor can be improved.

Note that, while methods to introduce chlorine elements (Cl) in the silicon oxide film include the conventionally used HCl oxidation method (an oxidation method by oxygen (O₂) and hydrogen chloride (HCl)), it is very difficult in the HCl oxidation method to form the top Si oxide film 506 to be thick on the silicon nitride film 505 having an anti-oxidation property. Though it is principally possible, a film thickness of a top Si oxide film formed by an oxidation at a common temperature and within a common time is about 3 nm at most, and it is considered to be impossible to form the top Si oxide film 506 having a thickness of 3 nm or more unlike the fifth embodiment. In the thermal oxidation method of the fifth embodiment, it is possible to form the sufficiently thick top Si oxide film 506 even on the silicon nitride film 505 having an anti-oxidation property. Note that, in order to ensure a charge retention property, the film thickness of the top Si oxide film 506 of the MONOS memory transistor is generally made to be about 3 nm or more. Thus, the method of forming the top Si oxide film 506 by the conventional HCl oxidation method is difficult to obtain the desired top Si oxide film 506 practically. Therefore, in the case where the top Si oxide film 506 of 3 nm or more is formed on the silicon nitride film 505 to be the charge accumulating film and the top Si oxide film contains chlorine (Cl), it can be considered that the top Si oxide film 506 is formed by the thermal oxidation method according to the fifth embodiment. Note that these absolute values of the measurement voltage conditions and film thicknesses of the thin films cited in the fifth embodiment are simply examples, and the present invention is not limited by these numerical values.

Typical effects obtained by the technical ideas described in the first to fifth embodiments above are as follows. For example, since a sufficient oxidation rate (film-formation rate) can be obtained even when the thermal oxidation temperature to form the silicon oxide film is reduced, the oxidation temperature (heat treatment temperature) and the heat treatment time can be reduced in the manufacture process of the semiconductor device. Particularly, in the case of applying the technical ideas to manufactures of a MOS transistor and a MONOS transistor, variations in the impurities introduced in the semiconductor substrate can be suppressed, so that variations in the threshold voltage can be reduced. In addition, in the normal methods for a silicon nitride film and a SiC substrate, when the thermal oxidation methods of the present embodiments are applied to oxidation processing of materials having a very low oxidation rate (film-formation rate), a sufficient oxidation rate to form a silicon oxide film can be obtained, so that temperature reduction in the whole process and time reduction in the heat treatment can be achieved. Moreover, since it is possible to reduce the heat treatment time also in the process requiring a thick thermal oxidation film (silicon oxide film) according to the present embodiments, a sufficient throughput can be obtained even for an oxidation apparatus (heat treatment apparatus) of the wafer-by-wafer system.

In the foregoing, the invention made by the inventors of the present invention has been concretely described based on the embodiments. However, it is needless to say that the present invention is not limited to the foregoing embodiments and various modifications and alterations can be made within the scope of the present invention.

The present invention is widely applicable to the manufacturing industry for manufacturing semiconductor devices.

What is claimed is:

1. A method of manufacturing a semiconductor device including a MISFET, the method comprising the steps of:
(a) introducing impurities into a semiconductor substrate, thereby forming a semiconductor region; and
(b) thermally oxidizing the semiconductor substrate or a processed film formed on the semiconductor substrate, thereby forming a silicon oxide film after the step (a), wherein
the step (b) includes the steps of:
(b1) introducing source gases including a gas containing ozone and a compound gas containing a halogen element onto the semiconductor substrate; and
(b2) heating the semiconductor substrate after the step (b1).

2. The method of manufacturing the semiconductor device according to claim 1, wherein
the step (b1) introduces the compound gas containing a halogen element subsequent to introducing the gas containing ozone onto the semiconductor substrate.

3. The method of manufacturing the semiconductor device according to claim 1, wherein
the step (b2) heats the semiconductor substrate at a temperature higher than or equal to a temperature at which the compound gas containing a halogen element is dissociated into radicals.

4. The method of manufacturing the semiconductor device according to claim 1, wherein
the compound gas containing a halogen element includes either of hydrogen fluoride, hydrogen chloride, hydrogen bromide, nitrogen trifluoride or chlorine trifluoride.

5. The method of manufacturing the semiconductor device according to claim 1, wherein
the gas containing ozone contains ozone and oxygen.

6. The method of manufacturing the semiconductor device according to claim 5, wherein
an ozone concentration in the gas containing ozone defined by “ozone flow rate/(ozone flow rate+oxygen flow rate)×100” is 50% or more.

7. The method of manufacturing the semiconductor device according to claim 1, wherein,
in a case of taking a ozone flow rate in the source gases as “a”, a flow rate of the compound gas containing a halogen element as “b”, and a concentration of the compound gas containing a halogen element in the source gases as “A”, and defining A=b/(a+b),
based on a relationship of the concentration A of the gas containing a halogen element in the source gases and a film thickness of the formed silicon oxide film, the concentration A of the gas containing a halogen element in the source gases is set to be smaller than or equal to a value corresponding to a maximal value of the film thickness of the formed silicon oxide film.

8. The method of manufacturing the semiconductor device according to claim 1, wherein
the silicon oxide film contains a halogen element.

9. The method of manufacturing the semiconductor device according to claim 8, wherein
the halogen element is either of fluorine, chlorine, or bromine.

10. The method of manufacturing the semiconductor device according to claim 1, wherein
the processed film is a silicon nitride film, and
the film thickness of the silicon oxide film formed on the silicon nitride film is 2 to 10 nm, and the silicon oxide film contains the halogen element.

11. The method of manufacturing the semiconductor device according to claim 1, wherein
the semiconductor region formed in the step (a) is a well,
the method comprises the step of (c) forming device isolation regions in the semiconductor substrate after the step (a), wherein
the step (c) comprises the steps of:
(c1) forming device isolation trenches in a device formation surface of the semiconductor substrate;
(c2) forming a first silicon oxide film on the device formation surface of the semiconductor substrate including inner walls of the device isolation trenches after the step (c1);
(c3) forming a second silicon oxide film on the device formation surface of the semiconductor substrate so as to bury the device isolation trenches after the step (c2); and
(c4) forming the device isolation regions in the semiconductor substrate with remaining the first silicon oxide film and the second silicon oxide film only in the insides of the device isolation trenches by removing the first silicon oxide film and the second silicon oxide film formed on the device formation surface of the semiconductor substrate by a chemical mechanical polishing method after the step (c3), and wherein
the step (c2) forms the first silicon oxide film by performing the step (b).

12. The method of manufacturing the semiconductor device according to claim 1, wherein
the semiconductor region formed in the step (a) is a threshold voltage adjustment semiconductor region, wherein
the method comprises the steps of:
(d) forming a gate insulating film on the semiconductor substrate after the step (a);
(e) forming a first conductive film on the gate insulating film;
(f) forming a gate electrode by patterning the first conductive film; and
(g) forming a source region and a drain region in the semiconductor substrate in alignment with the gate electrode, and wherein
the step (d) forms the gate insulating film formed of the silicon oxide film by performing the step (b).

13. The method of manufacturing the semiconductor device according to claim 1, wherein
the semiconductor region formed in the step (a) is a threshold voltage adjustment semiconductor region, wherein
the method comprises the steps of:
(h) forming a first potential barrier film on the semiconductor substrate after the step (a);
(i) forming a charge accumulating film on the first potential barrier film after the step (h);
(j) forming a second potential barrier film on the charge accumulating film after the step (i);
(k) forming a second conductive film on the second potential barrier film after the step (j);
(l) forming a gate electrode by patterning the second conductive film; and
(m) forming a source region and a drain region in the semiconductor substrate in alignment with the gate electrode, and wherein
the step (h) forms the first potential barrier film formed of the silicon oxide film by performing the step (b).

14. The method of manufacturing the semiconductor device according to claim 13, wherein
the step (j) forms the second potential barrier film formed of the silicon oxide film by performing the step (b).

15. The method of manufacturing the semiconductor device according to claim 14, wherein
the charge accumulating film formed in the step (i) is a silicon nitride film.

16. The method of manufacturing the semiconductor device according to claim 15, wherein
the second potential barrier film formed in the step (j) contains either halogen element of fluorine, chlorine, or bromine.
